(19) United States
(12) Patent Application Publication
(10) Pub. No.: US 2016/0027778 A1
(43) Pub. Date: Jan. 28, 2016

(54) SEMICONDUCTOR DEVICE

(71) Applicants: Yoshikazu MORIWAKI, (US); Kanta SAINO, (US); PS4 Luxco S.a.r.l., Luxembourg (LU)

(72) Inventors: Yoshikazu Moriwaki, Tokyo (JP); Kanta Saino, Tokyo (JP)

(21) Appl. No.: 14/774,914

(22) PCT Filed: Mar. 10, 2014
(86) PCT No.: PCT/JP2014/056090

§ 371 Date: Sep. 11, 2015

(30) Foreign Application Priority Data
Mar. 13, 2013 (JP) 2013-050344

(51) Int. Cl. H01L 27/092; H01L 29/06

(52) U.S. Cl. CPC H01L 27/092; H01L 29/0649

(57) ABSTRACT

One semiconductor device includes a first active region provided on a semiconductor substrate in which a transistor having a high dielectric constant gate insulating film, a gate electrode, and a diffusion layer is disposed, an element separation region that is in contact with and surrounds the first active region, and a dummy active region that is in contact with the element separation region.

### TECHNICAL FIELD

The present invention relates to a semiconductor device and relates for example to a semiconductor device including a field effect transistor utilizing an insulating film of high dielectric constant, having a higher dielectric constant than the dielectric constant of silicon oxide, in the gate insulating film.

### BACKGROUND ART

In order to improve MOSFET transistor performance, a high k metal gate (HKMG) construction is employed, in which, instead of a gate insulating film whose chief constituent is silicon dioxide, high dielectric constant insulating film, called high-k, is used, and, for the gate electrode, instead of poly-Si, a metal film is used.

For example, the planar-type MOSFET employing an HKMG structure disclosed in Patent Reference 1 (Laid-open Japanese Patent Application 2012-099517) comprises a gate insulating film made of high dielectric constant material formed on a substrate, a metal gate electrode formed on the gate insulating film, and a sidewall spacer formed on the sidewall of the metal gate electrode. Additionally, there is provided an offset spacer that is formed between the metal gate electrode sidewall and the insidewall of the sidewall spacer. (See Patent Reference 1, FIG. 1, paragraph 0014)

For example in Patent Reference 4 (Laid-open Japanese Patent Application 2013-026494), there is disclosed a field effect transistor provided in a peripheral circuit forming region constituted by a planar-type MOSFET employing an HKMG construction in which a high dielectric constant insulating film is employed as the gate insulating film. A silicon oxide film is formed on the main face of the peripheral circuit forming region. On a P well, in order from the semiconductor substrate side, there are formed an HfO2 (hafnium oxide) film, titanium nitride film (metal film) and a polysilicon film (conductive film): the silicon oxide film and the HfO2 film constitute a gate insulating film and the titanium nitride film and polysilicon film constitute a gate electrode. Also, on an N well, in order from the semiconductor substrate side, there are formed an HfO2 film, Al2O3 (aluminum oxide) film, a titanium nitride film and a polysilicon film: the silicon oxide film, HfO2 film and Al2O3 film constitute a gate insulating film and the titanium nitride film and polysilicon film constitute a gate electrode. (See Patent Reference 4, FIG. 3, paragraph 0019)
In Patent Reference 2 (Laid-open Japanese Patent Application 2009-231563), in a semiconductor device including a plurality of planar-type MISFETs, there is disclosed a construction in which, when forming element isolating regions, which are used to isolate the element regions of each MISFET, by implantation of STI (Shallow Trench Isolation) trenches in a coating-type insulating film, the element isolating region is divided into a second element isolating region surrounding a first element isolating region, providing a prescribed separation with respect to the first element isolating region that surrounds the element region. The semiconductor substrate is present between the first element isolating region and the second element isolating region and this region is utilized as a dummy element region. When the element isolating region is divided into the first element isolating region and the second element isolating region, the volume of the coating-type insulating film that is implanted in the STI trenches is reduced and the tensile stress resulting from thermal contraction is also lowered, with the result that the beneficial effect of preventing generation of crystal defects is manifested. (See Patent Reference 2, FIG. 1, paragraph 0019 and paragraph 0022)
In Patent Reference 3 (Laid-open Japanese Patent Application Number 2007-250705), a construction is disclosed in which for example an element isolating region that isolates the element regions of pMOSFETs manufactured using N type wells provided on a P type semiconductor substrate and a well contact diffusion layer surrounding this element isolating region are provided, and a sub-contact diffusion layer is provided on the surface of the P type semiconductor substrate. The sub contact diffusion layer is a P type diffusion layer and is employed in applications where a substrate potential (sub potential) is supplied to the P type semiconductor substrate; the well contact diffusion layer is an N type diffusion layer and is employed in applications where a well potential is supplied to the N type wells. Consequently, the sub contact diffusion layer is connected with electrodes for application of substrate potential (sub potential) through the contacts and the well contact diffusion layer is connected with electrodes for application of well potential through the contacts. (See Patent Reference 3, FIG. 1, paragraph 0025, and paragraph 0026)

### PATENT REFERENCES

Patent Reference 1: Laid-open Japanese Patent Application Number 2012-099517
Patent Reference 2: Laid-open Japanese Patent Application Number 2009-231563
Patent Reference 3: Laid-open Japanese Patent Application Number 2007-250705
Patent Reference 4: Laid-open Japanese Patent Application Number 2013-026494

### DISCLOSURE OF THE INVENTION

### Problem that the Invention is Intended to Solve

In a planar-type MOSFET employing a planar-type MOSFET, in particular, of HKMG construction, in which an HK gate insulating film is employed and that is provided in a peripheral circuit region, as shown in FIG. 19, in order to form an LDD (Lightly Doped Drain) construction by application of the self-aligning technique, there are provided a sidewall spacer (SD sidewall) formed at the sidewall of the metal gate electrode, and an offset spacer (Offset sidewall) formed between the metal gate electrode sidewall and the sidewall spacer insidewall.

In Patent Reference 4 (Laid-open Japanese Patent Application Number 2013-026494), it is reported that, when silicon oxide is adopted as the material constituting the aforementioned sidewall spacer (SD sidewall) and offset spacer (Offset sidewall), this brings about an increase in the film thickness (Equivalent Oxide Film Thickness (EOT)) of the gate insulating film during the manufacturing process and, in addition, that a negative fixed charge is induced in the gate insulating film. In particular, it is also reported that the increase in the film thickness of the gate insulating film (equivalent oxide film thickness (EOT)) when high dielectric constant insulating film is employed as the gate insulating film is more marked than when silicon oxide is employed as the gate insulating film. When a negative fixed charge is induced in the gate insulating film, a shift (in the case of an nMOSFFET, this is manifested as a rise in the threshold voltage Vt) in the threshold voltage Vt occurs and the effect caused by this induced negative fixed charge is more marked when high dielectric constant film is employed as the gate insulating film, than when silicon oxide is employed as the gate insulating film. Patent Reference 4 discloses means for solving the problem that appears when silicon oxide is employed as the material constituting the aforementioned sidewall spacer (SD sidewall) and offset spacer (Offset sidewall). Patent Reference 4 discloses means for avoiding the shift in the threshold value Vt by suppressing induction of the negative fixed charge in the gate insulating film and the increase in EOT of the gate insulating film, by selecting silicon nitride as the material constituting the offset spacer (Offset sidewall) and selecting aluminum oxide (Al2O3) as the material constituting the aforementioned sidewall spacer (SD sidewall).

The present inventors discovered that, in a planar-type MOSFET employing an HKMG construction in the peripheral circuit region, the width W of the metal gate electrode becomes narrower and the threshold voltage Vt is considerably shifted (manifested, in the case of a planar-type NMOSFFET, as a rise in the threshold voltage Vt), even when the material constituting the sidewall spacer (SD sidewall) and the offset spacer (Offset sidewall) has been chosen as disclosed in the aforementioned Patent Reference 4.

The present invention solves the aforementioned newly discovered problem. Specifically, an object of the present invention is to provide means for suppressing the amount of shift of the threshold voltage Vt (manifested, in the case of a planar-type nMOSFFET, as the amount of increase in the threshold voltage Vt) that results from diminution in the gate width W of the metal electrode, in a planar-type MOSFET in which an HK gate insulating film is adopted, in particular, a planar-type MOSFET employing an HKMG construction, in a peripheral circuit region, when for example aluminum oxide (Al2O3) and silicon nitride are selected, instead of silicon oxide, as the material constituting the sidewall spacer and the offset spacer.

### Means for Solving the Problem

The present inventors have already investigated the beneficial effect, for example by applying the means disclosed in Patent Reference 4 in a planar-type nMOSFET employing an HKMG structure as shown in FIG. 19, of increasing the EOT of the gate insulating film, suppressing induction of negative fixed charge in the gate insulating film and so avoiding the shift in threshold voltage Vt, by selecting aluminum oxide (Al2O3) as the material constituting the sidewall spacer (SD sidewall) and selecting silicon nitride as the material constituting the offset spacer (Offset sidewall).

The inventors discovered the phenomenon that, in a planar-type nMOSFET in which the gate width W of the metal gate electrode is reduced and an HKMG construction is adopted, the threshold voltage Vt is shifted (manifested, in the case of a planar-type nMOSFFET, as a rise in the threshold voltage Vt), even when a construction is selected in which increase in the EOT of the gate insulating film and induction of negative fixed charge in the gate insulating film are suppressed. As a result of study of means of suppressing the amount of shift of the threshold voltage Vt (manifested, in the case of a planar-type nMOSFFET, as increase in the amount of the threshold voltage Vt) that is caused by decrease in the gate width W of this metal gate electrode, the present inventors discovered that, in for example a planar-type nMOSFET wherein an HKMG construction as shown in FIG. 19 is adopted, the amount of shift of the threshold voltage Vt caused by decrease in the gate width W of the metal gate electrode could be markedly suppressed, compared with the case where no “dummy active region” is provided, by the addition of a construction in which, as shown in FIG. 1, this is surrounded on four sides by a “dummy active region” adjoining a first element isolating region 2 provided at the periphery of the first active region 3 where the planar-type nMOSFET is arranged.

Based on the aforementioned discovery, the inventors conducted further studies, as result of which they conceived that the beneficial effect of suppressing the amount of shift of the threshold voltage Vt with decrease in the gate width W of the metal gate electrode is manifested not only in the case of the provision of a “dummy active region” as shown in FIG. 1, but also when the various arrangements of “dummy active regions” to be described are adopted, and thereby perfected the present invention.

The present inventors found that the shift (manifested as a rise in the threshold voltage Vt in the case of a planar-type nMOSFFET) in the threshold voltage Vt that is found when silicon oxide is employed as the material constituting the sidewall spacer and the offset spacer is caused by increase in the EOT of the gate insulating film and induction of negative fixed charge in the gate insulating film, as a result of admixture of impurities such as oxidizing agents into the HK gate insulating film. Consequently, if admixture of impurities such as oxidizing agents into the HK gate insulating film is avoided, for example by employing aluminum oxide and silicon nitride as the materials constituting the sidewall spacer and the offset spacer, instead of silicon oxide, increase in the EOT of the gate insulating film and induction of negative fixed charge in the gate insulating film can be avoided. As a result, the beneficial effect is obtained of suppressing the shift of the threshold voltage Vt caused by increase in the EOT of the gate insulating film and induction of negative fixed charge in the gate insulating film. This beneficial effect is not restricted to the case where the gate electrode formed on the gate insulating film is a metal gate electrode but is manifested in the same way even in the case of a polysilicon gate electrode.

On the other hand, the inventors discovered that a shift in the threshold voltage Vt with decrease in the aforementioned gate width W occurs even in the case where the technique of increasing the EOT of the gate insulating film and avoiding induction of negative fixed charge in the gate insulating film is adopted. In addition, the inventors discovered that the shift that occurs in the threshold voltage Vt with decrease in the gate width W is not restricted to the case where the gate electrode that is formed on the gate insulating film is a metal gate electrode but occurs also in the case where this is a polysilicon gate electrode. The inventors discovered that the beneficial effect of suppressing the shift in the threshold voltage Vt with decrease in the aforementioned gate width W achieved by the provision of the “dummy active region” is not restricted to the case where the gate electrode that is formed on the gate insulating film is a metal gate electrode, but is likewise manifested in the case where this is a polysilicon gate electrode.

Semiconductor devices according to the present invention include the following two modes.

A first mode of a semiconductor device according to the present invention consists in a semiconductor device characterized in that it comprises: a first active region wherein a transistor having a high dielectric constant gate insulating film, a gate electrode and diffusion layer is arranged provided on a semiconductor substrate; an element isolating region contiguous with and surrounding said first active region; and a dummy active region contiguous with said element isolating region.

In this first mode, said dummy active region can be a “first construction” comprising:

a first dummy active region extending in a first direction; and
a second dummy active region extending in a second direction different from said first direction and contiguous with said first dummy active region.

Said dummy active region can be a “second construction” comprising: a first dummy active region and a second dummy active region that face each other in a first direction; and

said first active region may be arranged between said first dummy active region and said second dummy active region.

When the “second construction” is selected, for said dummy active region, there may be additionally selected a “third construction” comprising a third dummy active region contiguous with said first dummy active region and said second dummy active region.

Also, for said dummy active region,

there may be further selected a “fourth construction”
comprising a third dummy active region and a fourth dummy active region contiguous with said first dummy active region and said second dummy active region;
arranged so that said first active region is connected with and surrounded by said first dummy active region, said second dummy active region, said third dummy active region and said fourth dummy active region.

Alternatively, said dummy active region may comprise a fifth dummy active region and a sixth dummy active region that face each other in a second direction different from said first direction, and

a “fourth construction” can be adopted in which said first active region is arranged so as to be surrounded by said first dummy active region, said second dummy active region, said fifth dummy active region and said sixth dummy active region.

In a first mode in a semiconductor device according to the present invention, the high dielectric constant gate insulating film preferably contains at least one material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃.

Preferably the gate electrode includes at least one metallic element selected from the group consisting of Ti, W, Ta, Ru and Al.

Also, a construction may be adopted in which impurity is implanted in said dummy active region.

In this case, preferably the conduction type of said diffusion layer and the conduction type of said impurity that is implanted in said dummy active region are the same.

In addition, a “fifth construction” may be adopted, in which a plurality of transistors respectively having a high dielectric constant gate insulating film, a gate electrode and a diffusion layer are arranged in the region surrounded by the element isolating region that is surrounded by said dummy active region.

A construction may be adopted wherein a plurality of semiconductor devices are provided on said semiconductor substrate and said plurality of semiconductor devices include at least one dummy active region as aforesaid in the “first construction” to “fourth construction” respectively described above.

In said first mode, a “sixth construction” may be adopted wherein said dummy active region extends in the first direction, and further comprises a first diffusion layer and second diffusion layer that are contiguous with said element isolating region and extend in the second direction different from said first direction, with said first active region arranged therebetween, and

a third diffusion layer that extends in said first direction, is connected with said first diffusion layer and said second diffusion layer, with said first active region arranged between this and said dummy active region, and
said first diffusion layer, said second diffusion layer and said third diffusion layer are supplied with a fixed potential.

In a second mode, a semiconductor device according to the present invention

is characterized in that it comprises:
provided on a semiconductor substrate,
a first transistor having a first high dielectric constant gate insulating film, a first metal gate electrode, a first diffusion layer and a second diffusion layer;
a second transistor having a second high dielectric constant gate insulating film, a second metal gate electrode, and said second diffusion layer and third diffusion layer;
a first element isolating region surrounding and contiguous with said first diffusion layer, said second diffusion layer and said third diffusion layer;
a first dummy active region contiguous with and surrounding on four sides said first element isolating region; and
a second element isolating region contiguous with and surrounding on four sides said first dummy active region.

In said second mode,

a “seventh construction” may be adopted wherein said first metal gate electrode and said second metal gate electrode extend in intersecting fashion over said first dummy active region and are connected by the first gate wiring.

In this case, an “eighth construction” may be adopted wherein there are provided on said semiconductor substrate:

a third transistor having a third high dielectric constant gate insulating film, a third metal gate electrode, a fourth diffusion layer and a fifth diffusion layer;
a fourth transistor having a fourth high dielectric constant gate insulating film, a fourth metal gate electrode, said fifth diffusion layer and sixth diffusion layer;
a third element isolating region contiguous with and surrounding said fourth diffusion layer, said fifth diffusion layer and said sixth diffusion layer;
a second dummy active region contiguous with and surrounding on four sides said third element isolating region; and
a fourth element isolating region contiguous with and surrounding on four sides said second dummy active region;
wherein said third metal gate electrode and said fourth metal gate electrode extend in intersecting fashion over said second dummy active region and are connected by the second gate wiring, and said first gate wiring and said second gate wiring are connected through the first conductive wiring.

Preferably, when the “eighth construction” is adopted, a “ninth construction” is adopted wherein

said first transistor and said second transistor are N channel-type transistors and said third transistor and said fourth transistor are P channel-type transistors.

In this case, preferably

the input signal terminal is connected with said first conductive wiring,
a first potential is supplied to said first diffusion layer and said third diffusion layer,
a second potential is supplied to said fourth diffusion layer and said sixth diffusion layer,
and said second diffusion layer and said fifth diffusion layer are connected with the output signal terminal through the second conductive wiring.

Also, preferably,

the respective conduction types of said first diffusion layer, said second diffusion layer and said third diffusion layer, and the conduction type of the first impurity that is implanted in said first dummy active region are N type, and
the respective conduction types of said fourth diffusion layer, said fifth diffusion layer and said sixth diffusion layer, and the conduction type of the second impurity that is implanted in said second dummy active region are P type.

In a second mode in a semiconductor device according to the present invention,

preferably said first high dielectric constant gate insulating film, said second high dielectric constant gate insulating film, said third high dielectric constant gate insulating film and said fourth high dielectric constant gate insulating film respectively include at least one material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃, and
said first metal gate electrode, said second metal gate electrode, said third metal gate electrode and said fourth metal gate electrode respectively include at least one metallic element selected from the group consisting of Ti, W, Ta, Ru and Al.

### Beneficial Effect of the Invention

In a semiconductor device according to the present invention, in a planar-type MOSFET employing an HK gate insulating film, for example a planar-type MOSFET utilizing an HKMG structure, the amount of shift of the threshold voltage Vt produced by reduction in the gate width W of the aforementioned planar MOSFET that is formed in the first active region can be greatly reduced, compared with the condition where no dummy active region is provided, by providing a first element isolating region surrounding the first active region that forms this planar MOSFET and providing a dummy active region that is contiguous with this first element isolating region.

### BRIEF DESCRIPTION OF THE DRAWINGS

FIG. 1 is a plan view showing diagrammatically the construction of a semiconductor device 100 constituting an example of a semiconductor device according to a first embodiment of the present invention.

FIG. 2 is a cross-sectional view showing diagrammatically the construction exposed at the cross section indicated by A-A′ in FIG. 1 in the semiconductor device 100.

FIG. 3 is a plan view showing diagrammatically the construction of a semiconductor device 200 constituting an example of a semiconductor device according to a second embodiment of the present invention.

FIG. 4-1 is a plan view showing diagrammatically the construction of a semiconductor device 300 constituting an example of a semiconductor device according to a third embodiment of the present invention.

FIG. 4-2 is a plan view showing diagrammatically the construction of a semiconductor device 300-1 constituting another example of a semiconductor device according to the third embodiment of the present invention.

FIG. 5-1 is a plan view showing diagrammatically the construction of a semiconductor device 400 constituting an example of a semiconductor device according to a fourth embodiment of the present invention.

FIG. 5-2 is a plan view showing diagrammatically the construction of a semiconductor device 400-1 constituting another example of a semiconductor device according to the fourth embodiment of the present invention.

FIG. 6 is a plan view showing diagrammatically the construction of a semiconductor device 500 constituting an example of a semiconductor device according to a fifth embodiment of the present invention.

FIG. 7 is a plan view showing diagrammatically the construction of a semiconductor device 600 constituting an example of a semiconductor device according to a sixth embodiment of the present invention.

FIG. 8 is a cross-sectional view showing diagrammatically the construction of a semiconductor device 700 constituting an example of a semiconductor device according to a seventh embodiment of the present invention.

FIG. 9 is a cross-sectional view showing diagrammatically the construction of a semiconductor device 800 constituting an example of a semiconductor device according to an eighth embodiment of the present invention.

FIG. 10-1 is a plan view showing diagrammatically the construction of a semiconductor device 900 constituting an example of a semiconductor device according to a ninth embodiment of the present invention, the semiconductor device 900 constituting a CMOS inverter.

FIG. 10-2 is a plan view showing diagrammatically the construction of a semiconductor device 900-1 constituting another example of a semiconductor device according to a ninth embodiment of the present invention, the semiconductor device 900-1 constituting a CMOS inverter.

FIG. 11 is a view showing a comparison of the measurement results regarding the dependence of the threshold voltage Vt on the gate width W in the case where no dummy active region is provided (dummy active region absent) and in the case where a dummy active region according to the first embodiment is provided (dummy active region present), in an N type MOS transistor of planar construction employing an HKMG construction, comprising a spacer film made of silicon nitride and a sidewall insulating film made of silicon oxide.

FIG. 12 is a plan view showing diagrammatically the manufacturing process of a first element isolating region 2 and a second element isolating region 4, in the manufacturing process of a semiconductor device 100, constituting an example of a semiconductor device according to a first embodiment of the present invention, having the construction shown in FIG. 1 and FIG. 2.

FIG. 13 is a cross-sectional view showing diagrammatically the forming process of a first element isolating region 2 and a second element isolating region 4 in the process of manufacturing a semiconductor device 100 constituting an example of a semiconductor device according to a first embodiment of the present invention, having the construction shown in FIG. 1 and FIG. 2.

FIG. 14 is a plan view showing diagrammatically the process of forming an LDD region 7 and an impurity diffusion region 6, utilizing the spacer film 19 and sidewall insulating film 14 provided on the sidewall of the gate electrode 12, during the process of manufacturing a semiconductor device 100 constituting an example of a semiconductor device according to a first embodiment of the present invention, having the construction shown in FIG. 1 and FIG. 2.

FIG. 15 is a cross-sectional view showing diagrammatically the process of forming an LDD region 7 and impurity diffusion layer 6, utilizing the spacer film 19 and sidewall insulating film 14 provided in the sidewall of the gate electrode 12, during the process of manufacturing a semiconductor device 100 constituting an example of a semiconductor device according to a first embodiment of the present invention, having the construction shown in FIG. 1 and FIG. 2.

FIG. 16 is a plan view showing diagrammatically a construction in which a plurality of transistors 50 comprising a first active region surrounded by a first element isolating region are arranged on a semiconductor substrate, a dummy active region 5 is provided surrounding the periphery of the transistors 50, and a second element isolating region 32 is provided surrounding this entire dummy active region 5.

FIG. 17 is a plan view showing diagrammatically the arrangement of a plurality of semiconductor devices, namely, a semiconductor device 100, a semiconductor device 300, a semiconductor device 400 and a semiconductor device 500 in a chip 1000 constituting an example of a chip in which a plurality of semiconductor devices according to the present invention are arranged on the same semiconductor substrate.

FIG. 18 is a plan view showing diagrammatically the construction of transistors 50, of which a plurality are arranged on a semiconductor substrate, in the construction shown in FIG. 16.

FIG. 19 is a cross-sectional view showing diagrammatically an example of the construction of an N type MOSFET of HKMG construction, employing a sidewall insulating film (SD-Sidewall) made for example of aluminum oxide and a spacer film (Offset-Sidewall) made of silicon nitride.

FIG. 20 is a view showing diagrammatically an example of a CMOS inverter circuit.

### EXPLANATION OF THE REFERENCE SYMBOLS

1 Silicon substrate
2 First element isolating region
3 First active region
3A First active region
3B First active region
3C First active region
3D First active region
3E First active region
4 Second element isolating region
5 Dummy active region
5A Dummy active region
5B Dummy active region
5C Dummy active region
5D Dummy active region
6 Impurity diffusion layer
6A Impurity diffusion layer
6B Impurity diffusion layer
7 LDD region
7A LDD region
7B LDD region
8 First interlayer insulating film
9 Gate insulating film
10 First conductive film
11 Second conductive film
12 Gate electrode
12A Gate electrode
12B Gate electrode
12C Gate electrode
13 Mask film
14 Sidewall insulating film
15 First contact plug
15A First contact plug
15B First contact plug
15C First contact plug
16 First wiring
16A First wiring
16B First wiring
16C First wiring
17 Second contact plug
18 Second wiring
19 Spacer film
20 Insulating film
21 High dielectric constant insulating film
22 Gate insulating film (high dielectric constant gate insulating film)
23 Metal film
24 First polysilicon film
25 Gate electrode (metal gate electrode)
26 Second polysilicon film
27 Tungsten film
28 Conductive layer
29 Cap film
30 First transistor (N type MOSFET)
31 Second transistor (P type MOSFET)
32 Second active region (well region)
33 Third contact plug
34 Third wiring
35 Fourth wiring
40 First isolating trench
41 Second isolating trench
50 Transistor (surrounded by first element isolating region)
100 Semiconductor device
200 Semiconductor device
300 Semiconductor device
300-1 Semiconductor device
400 Semiconductor device
400-1 Semiconductor device
500 Semiconductor device
600 Semiconductor device
700 Semiconductor device
800 Semiconductor device
900 Semiconductor device
900-1 Semiconductor device
1000 Chip (semiconductor substrate chip)

### BEST MODE FOR PUTTING THE INVENTION INTO PRACTICE

A semiconductor device according to the present invention is described in more detail below.

### First Embodiment

A semiconductor device according to a first embodiment of the present invention will now be described with reference to the drawings.

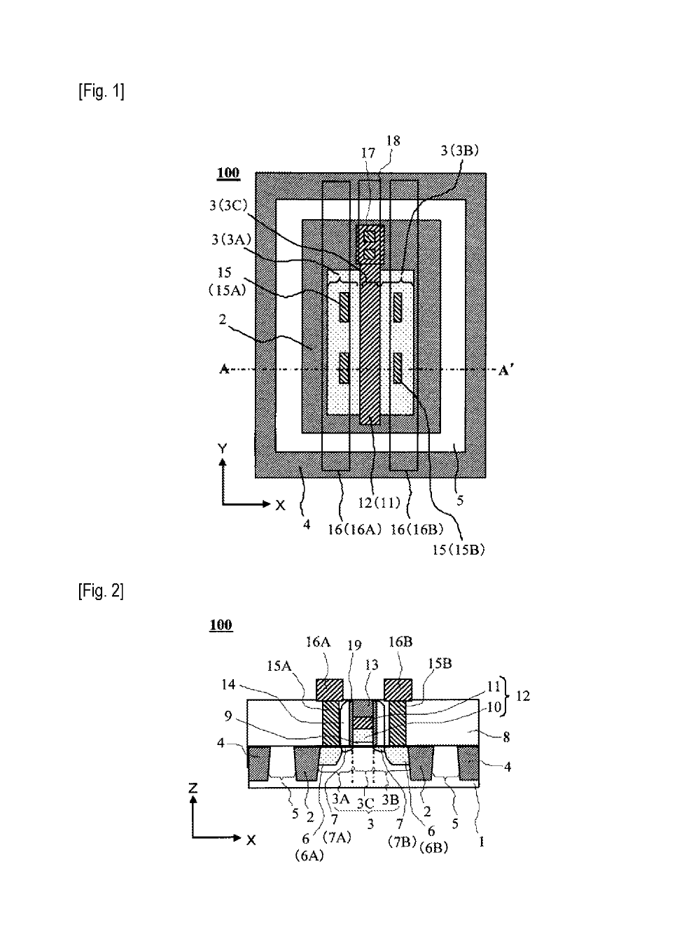

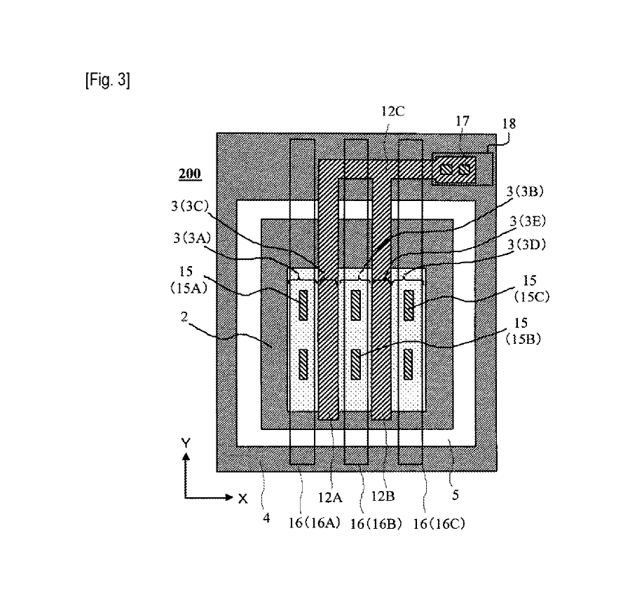

FIG. 1 is a plan view showing an example of the construction of a semiconductor device 100 according to a first embodiment and FIG. 2 is a cross-sectional view along the line A-A′ of FIG. 1. However, in FIG. 1, in order to clarify the arrangement of the structural elements, the interlayer insulating film and the wiring that are arranged above the transistor are shown as transparent. Also, according to the first embodiment, in the semiconductor device 100 constituted by portions relating to the first element isolating region, first active region, dummy active region and transistor, a silicon substrate is assumed to be employed as the semiconductor substrate constituting the base. Furthermore, the term wafer will be used to refer to both the condition during the process of manufacturing the semiconductor device or devices 100 on the semiconductor substrate and to the condition in which the semiconductor device or devices 100 have been formed on the semiconductor substrate. A plurality of chips formed with semiconductor devices according to the first embodiment and formed with semiconductor devices other than these may be arranged on the wafer.

First of all, the arrangement of a first element isolating region 2, a first active region 3, a dummy active region 5, and a second element isolating region 4 constituting a semiconductor device 100 according to the first embodiment will be described with reference to FIG. 1. The island-shaped first active region 3 is provided on the upper surface of the silicon substrate; its periphery is surrounded by the ring-shaped first element isolating region 2. In the embodiment of FIG. 1, the first active region 3 is rectangular in shape and extends in the Y direction; however, it could also extend in the X direction and, furthermore, a plurality of first active regions 3 could be suitably arranged in the X direction or Y direction. The first element isolating region 2 is surrounded by the ring-shaped dummy active region 5, which is surrounded by the second element isolating region 4. Continuing the description in more detail, the first active region 3 is surrounded by the ring-shaped first element isolating region 2, the first element isolating region 2 is surrounded by the ring-shaped dummy active region 5, and the dummy active region 5 is surrounded by the second element isolating region 4. In the middle of the first active region 3 in the X direction, a single gate electrode 12 is arranged so as to cut across the first active region 3 in the Y direction. The first active region 3 comprises a first active region 3A that is arranged at one end in the X direction of the gate electrode 12, a first active region 3C that is overlaid on the gate electrode 12, adjacent to the first active region 3A, and a first active region 3B that is arranged at the other edge thereof, adjacent to the first active region 3C. Two first contact plugs 15A are arranged above the first active region 3A; a first wiring 16A that extends in the Y direction is arranged above the first contact plug 15A. Likewise, two first contact plugs 15B and a single first wiring 16B that extends in the Y direction are arranged above the first active region 3B and a gate electrode 12 is arranged above the first active region 3C. Hereinbelow, the first contact plugs 15A and 15B will be jointly referred to as the first contact plug 15 and the first wirings 16A and 16B will be jointly referred to as the first wiring 16. At least one end of the gate electrode 12 is expanded in width in the X direction while extending as far as a region where it overlaps the first element isolating region 2; two second contact plugs 17 are arranged above this expanded-width portion. In addition, a second wiring 18 that extends in the Y direction is arranged above the second contact plug 17.

Next, the construction of the semiconductor device 100 according to the first embodiment will be described with reference to FIG. 2. In FIG. 1, a planar MOS (metal oxide semiconductor) transistor construction was employed in the semiconductor device 100 according to the first embodiment, so, hereinbelow, a planar MOS transistor construction will be described. The planar MOS transistor is provided on the silicon substrate 1 in the first active region 3, sandwiched between this and the first element isolating region 2. The planar MOS transistor comprises a gate insulating film 9 covering the upper surface of the first active region 3C, a gate electrode 12 comprising a first conductive film 10 and second conductive film 11 covering the upper surface of the gate insulating film 9, and an impurity diffusion layer 6A constituting one or other of the source/drain regions provided above the first active region 3A, and an impurity diffusion layer 6B constituting the other of the source/drain regions provided above the first active region 3B. Also an LDD (Lightly Doped Drain) region 7A that plays the role of moderating the electrical field at the drain terminal is arranged so as to be adjacent to one edge of the impurity diffusion layer 6A and an LDD region 7B is likewise arranged at one edge of the impurity diffusion layer 6B. Hereinbelow, the impurity diffusion layers 6A and 6B will be jointly referred to as the impurity diffusion layer 6 and the LDD regions 7A and 7B will be jointly referred to as the LDD region 7. It should be noted that although, in the construction shown in FIG. 2, no impurity diffusion layer is arranged in the dummy active region 5, an impurity diffusion layer could be arranged therein. The upper surface of the gate electrode 12 constituting the planar MOS transistor is covered by a mask film 13 and the side face thereof is covered by a spacer film 19 and sidewall insulating film 14.

It should be noted that the planar MOS transistor is provided with an HKMG structure constituted by for example the gate insulating film 9 comprising a silicon oxide film and high dielectric constant insulating film and the first conductive film 10 comprising a metal film and polysilicon film. Also, by adopting a construction in which the side face of the metal electrode is covered by for example a spacer film 19 made of silicon nitride and a sidewall insulating film 14 made of aluminum oxide, increase in the EOT of the gate insulating film and induction of negative fixed charge in the gate insulating film can be suppressed and the shift in the threshold voltage Vt caused by the manufacturing process can be avoided.

The planar MOS transistor is buried in the first interlayer insulating film 8 and the first contact plug 15 (15A, 15B) and second contact plug 17, not shown, are arranged within the first interlayer insulating film 8. Thereupon, the impurity diffusion layer 6A is connected with the bottom face of the first contact plug 15A and the impurity diffusion layer 6B is connected with the bottom face of the first contact plug 15B. Although not shown, the gate electrode 12 is connected with the bottom face of the second contact plug 17. The first wiring 16 (16A, 16B) and the second wiring 18 are arranged at the upper face of the first interlayer insulating film 8. The upper face of the first contact plug 15A is connected with the bottom face of the first wiring 16A and the upper face of the first contact plug 15B is connected with the bottom face of the first wiring 16B. Also, although not shown, the upper face of the second contact plug 17 is connected with the bottom face of the second wiring 18. Consequently, the impurity diffusion layer 6A constituting the planar MOS transistor is connected with the first wiring 16A through the first contact plug 15A provided on the upper face of the impurity diffusion layer 6A and, likewise, the impurity diffusion layer 6B is connected with the first wiring 16B through the first contact plug 15B provided on the upper face of the impurity diffusion layer 6B. Also, although not shown, the gate electrode 12 is connected with the second wiring 18 through the second contact plug 17 that is provided on the upper face of the gate electrode 12.

The potential V_{dummy active region} of the ring-shaped dummy active region 5, which is a region sandwiched by the first element isolating region 2 and the second element isolating region 4, is substantially maintained at the same potential at all locations of the ring-shaped dummy active region 5. Specifically, when a ring-shaped dummy active region 5 is formed in the P type semiconductor substrate, the potential V_{dummy active region} of the ring-shaped dummy active region 5 is maintained at the substrate potential V_{substrate} that is supplied to the P type semiconductor substrate. As a result, the potential V_{active region-bottom-D} of the bottom portion of the first active region on the drain side and the potential V_{active region-bottom-S} of the bottom portion of the first active region on the source side, which are electrically linked through the narrow conductive path remaining below this ring-shaped dummy active region 5 and the first element isolating region 2, are maintained at a substantially constant potential in the same way as the potential V_{dummy active region} of the ring-shaped dummy active region 5. Consequently, fluctuation of the potential V_{active region bottom G} of the bottom portion of the first active region directly below the gate electrode 12 is suppressed, since the potential V_{active region-bottom-D} on the drain side and the potential V_{active region-bottom-S} on the source side are maintained at a substantially fixed potential.

It should be noted that, in the case of the semiconductor device 100 according to the first embodiment, the first active region 3 where a single planar MOS transistor is provided is surrounded by the ring-shaped dummy active region 5, with the first element isolating region 2 interposed. In the semiconductor device according to the present invention, the shape of the dummy active region 5 and the layout of the planar MOS transistor in the first active region 3 can be modified in various ways; various embodiments other than the first embodiment will therefore be described below. It should be noted that repetition of aspects of the description and drawings that are shared with the first embodiment is avoided and the description thus focuses on the differences that are characteristic of the respective embodiments.

### Second Embodiment

A semiconductor device according to a second embodiment of the present invention is described below with reference to the drawings.

FIG. 3 is a plan view showing the layout of a semiconductor device 200 according to a second embodiment. However, it should be noted that, in FIG. 3 also, in order to clarify the arrangement of the various structural elements, the interlayer insulating film and the wiring that are arranged above the transistor are shown as transparent: the same applies in all the subsequent plan views.

Referring to FIG. 3, the first element isolating region 2, first active region 3, dummy active region 5 and second element isolating region 4 constituting a semiconductor device 200 according to the second embodiment will be described. As shown in vertical cross section in the Y direction of the first active region 3, two gate electrodes 12 (12A, 12B) are arranged in the first active region 3. The first active region 3 comprises: a first active region 3A that is arranged in a position at one end of the gate electrode 12A in the X direction; a first active region 3C that overlies the gate electrode 12A and is adjacent to the first active region 3A; a first active region 3B that is positioned at the other end of the gate electrode 12A and at one end in the X direction of the gate electrode 12B; a first active region 3E that overlies the gate electrode 12B and that is adjacent to the first active region 3B; and a first active region 3D that is positioned at the other end of the gate electrode 12B. Specifically, in the first active region 3, there are respectively arranged: a planar MOS transistor constituted by the gate electrode 12A and the impurity diffusion layer 6 (not shown) provided on the first active regions 3A and 3B; and a planar MOS transistor constituted by the gate electrode 12B and the impurity diffusion layer 6 (not shown) provided on the first active regions 3B and 3D. Two first contact plugs 15C are arranged so as to overlie the upper surface of the first active region 3D and a first wiring 16C extending in the Y direction is arranged so as to overlie the upper face of the first contact plug 15C.

The respective ends of the two gate electrodes 12 (12A, 12B) span the dummy active region 5 and extend as far as the region overlying the second element isolating region 4. In addition, the two gate electrodes 12 (12A, 12B) are integrated so as to be united in the region overlying the second element isolating region 4 and furthermore extend in the X direction in the region overlying the second element isolating region 4. This integrated united gate electrode is termed the gate electrode 12C. In more detail, whereas one end of the gate electrode 12B extends in the Y direction and is integrated with the gate electrode 12C, one end of the gate electrode 12A extends in the Y direction and then extends further in the X direction before being integrated with the gate electrode 12C. In other words, three gate electrodes 12 (12A, 12B and 12C) are provided in the semiconductor device 200. One end of the gate electrode 12C is of expanded width in the Y direction and two second contact plugs 17 are arranged so as to overlie the upper face of this expanded-width portion. In addition, a second wiring 18 that extends in the X direction is arranged so as to overlie the upper surfaces of the second contact plugs 17.

It should be noted that, in the mode shown in FIG. 3, the first element isolating region 2 that surrounds the first active region 3 where the two planar MOS transistors are provided is surrounded by the dummy active region 5. The number of planar MOS transistors that are provided in the first active region 3 surrounded by the first element isolating region 2 may be at least three, but preferably a number in a range of up to 30 is selected. Also, when providing a plurality of planar MOS transistors, a mode may be employed in which the second contact plugs 17 that supply gate voltage to the gate electrode 12 are provided on the second element isolating region 4 and the arrangement of the gate electrodes 12 spans the dummy active region 5, or a mode may be employed in which the second contact plugs 17 are provided on the first element isolating region 2 but the arrangement of the gate electrodes does not span the dummy active region 5.

It should be noted that, in the semiconductor device 200 according to the second embodiment shown in FIG. 3, for example the gate insulating film 9 is constituted by a silicon oxide film and high dielectric constant insulating film, while the first conductive film 10 is constituted by a metal film and polysilicon film; in this way, a planar MOS transistor is produced having an HKMG construction. Also, if, for the metal gate electrode, a construction is adopted wherein the side face is covered by a spacer film 19 made of for example silicon nitride and a sidewall insulating film 14 made of for example aluminum oxide, increase in the EOT of the gate insulating film and induction of negative fixed charge in the gate insulating film are suppressed, resulting in a construction in which the shift of the threshold voltage Vt produced by the manufacturing process is avoided.

Also, in the construction shown in FIG. 3, since no impurity diffusion layer is arranged in the dummy active region 5, the portions where the gate electrodes 12 span the dummy active region 5 constitute MOS type diodes.

### Third Embodiment

A semiconductor device according to a third embodiment of the present invention is described below with reference to the drawings.

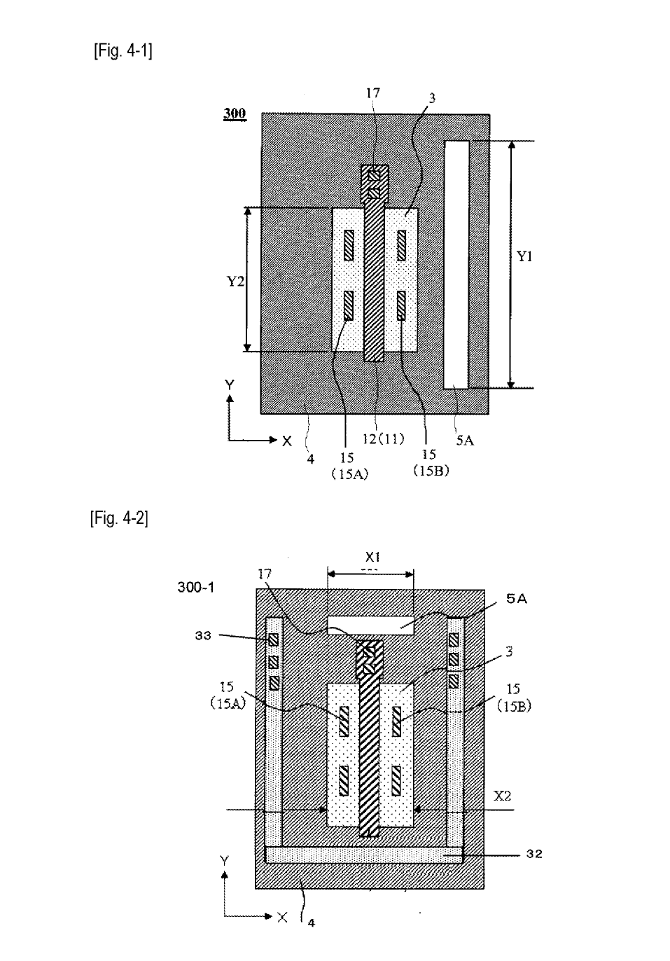

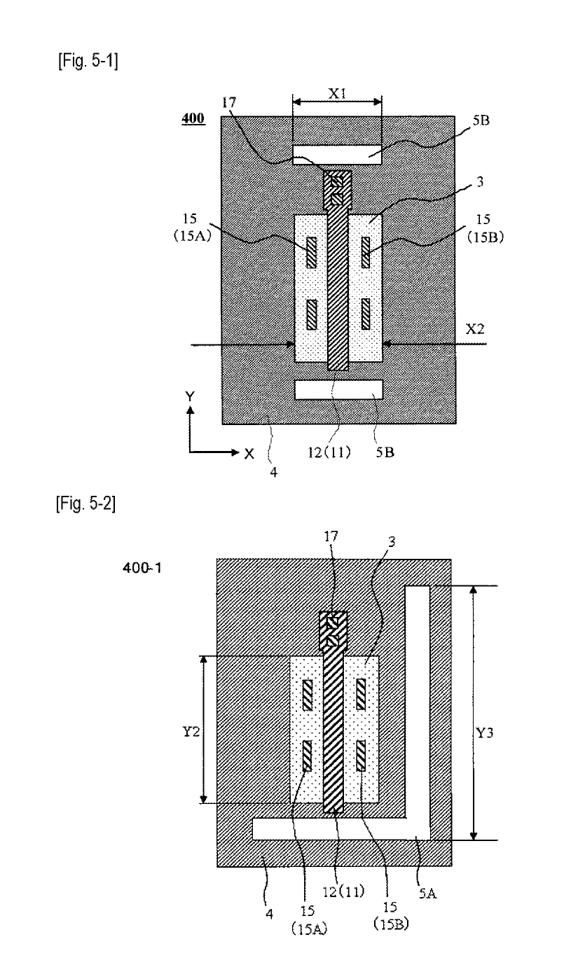

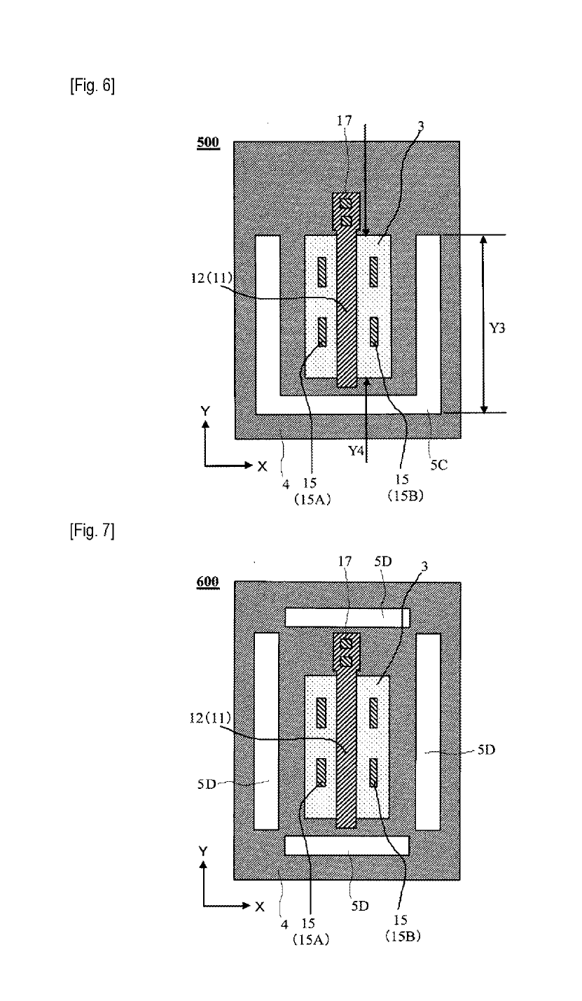

FIG. 4-1 is a plan view showing the construction of a semiconductor device 300 according to a third embodiment. It should be noted that, although, for convenience in description, in FIG. 4-1, FIG. 4-2, FIG. 5-1, FIG. 5-2, FIG. 6 and FIG. 7, the first wiring 16 (16A and 16B) and the second wiring 18 are not identified, their respective positions of arrangement are the same as in the case of the first embodiment shown in FIG. 1.

Referring to FIG. 4-1, the first active region 3, a dummy active region 5A and second element isolating region 4 constituting the semiconductor device 300 according to the third embodiment will be described.

The island-shaped first active region 3 is provided on the upper face of the silicon substrate and the periphery thereof is surrounded by the second element isolating region 4. A single dummy active region 5A is arranged, with the second element isolating region 4 interposed, at one edge in the X direction of the first active region 3. The dummy active region 5A is rectangular in shape and extends in the Y direction; the length Y1 thereof in the Y direction is longer than the length Y2 of the first active region 3 in the Y direction (Y1>Y2).

Depending on the case, the length Y1 in the Y direction may be the same as Y2 (Y1=Y2), or may be shorter than Y2 (Y1<Y2). However, if Y1<Y2, Y1 is reduced and the benefit of the provision of a “dummy active region” is reduced.

With the semiconductor device according to the third embodiment i.e. the semiconductor device 300 shown in FIG. 4-1, instead of the ring-shaped dummy active region, with regard to the rectangular first active region 3, a single dummy active region 5A is provided only at one edge thereof: no dummy active region is provided at the other three edges. As a result, at the three edges where no dummy active region is provided, in the first embodiment and second embodiment, the region where a “dummy active region” is provided sandwiched by the “first element isolating region 2” and “second element isolating region 4” includes a region where an “isolating trench” is formed, in which insulating film is buried. Consequently, at the three edges where no dummy active region is provided, the “first element isolating region 2” and the “second element isolating region 4” are linked, so that, as a whole, an integrated “element isolating region” is constituted. In the semiconductor device according to the third embodiment of the present invention, the “first element isolating region 2” and the “second element isolating region 4” are linked, so that, as a whole, an integrated “element isolating region”, termed a “second element isolating region 4” is constituted.

It should be noted that the position of arrangement of the dummy active region 5A is at the other edge in the X direction.

Furthermore, it is possible to select the position of arrangement of the dummy active region 5A at either of the edges in the Y direction, rather than at one edge in the X direction of the first active region 3.

FIG. 4-2 is a plan view showing the construction of a semiconductor device 300-1 according to the third embodiment.

Referring to FIG. 4-2, the first active region 3, dummy active region 5A and second element isolating region 4 constituting the semiconductor device 300-1 according to the third embodiment will be described.

The island-shaped first active region 3 is provided on the upper face of the silicon substrate and its periphery is surrounded by the second element isolating region 4. A single dummy active region 5A is arranged at one edge in the Y direction of the first active region 3, with the second element isolating region 4 interposed. The dummy active region 5A is of rectangular shape and extends in the X direction; its length X1 in the X direction is equal to the length X2 of the first active region 3 in the Y direction (X1=X2).

Depending on the case, the length X1 in the X direction may be selected to be longer than X2 (X1>X2) or may be selected to be shorter than X2 (X1<X2). However, if X1>X2, even if X1 is increased, the beneficial effect of providing a “dummy active region” is substantially the same as the beneficial effect in the case where X1=X2. On the other hand, if X1<X2, X1 is decreased and if finally substantially X1=0, the beneficial effect of providing a “dummy active region” is lost.

In the case of the semiconductor device 300-1 according to the third embodiment shown in FIG. 4-2, a U-shaped second active region 32 is arranged at the three edges where no dummy active region is provided. A diffusion layer is formed in this second active region 32 and, through the third contact plug, substrate potential V_{substrate} is supplied to the P type semiconductor substrate and well potential V_{well} is supplied to the well region.

The “U”-shaped second active region 32 has the same potential; the potential V_{second active region} of the second active region 32 is maintained at the substrate potential V_{substrate} or well potential V_{well} supplied through the third contact plug 33. The dummy active region 5A is electrically linked with the bottom portion of the second active region 32 through the residual conductive path at the bottom portion of the second element isolating region 4. Consequently, the potential V_{dummy active region-A} of the dummy active region 5A is maintained at a substantially fixed potential, like the potential V_{second active region} of the “U”-shaped second active region 32.

The bottom of the rectangular-shaped first active region 3 is electrically linked through the residual conductive path at the bottom of the second element isolating region 4 with the bottom of the “U”-shaped second active region 32 and the bottom of the dummy active region 5A: thus the potential V_{active region-bottom} of the bottom of the rectangular-shaped first active region 3 is maintained at a potential that is substantially equal to the potential V_{second active region} of the “U”-shaped second active region 32.

In the case of the semiconductor device 300-1 according to the third embodiment shown in FIG. 4-2, the dummy active region 5A and the “U”-shaped second active region 32 are arranged so as to surround the periphery of the rectangular first active region 3. At this point, just as in the case of the second element isolating region 4, a diffusion layer is provided also in the dummy active region 5A, and a mode can thus be selected whereby the potential V_{second active region} of the dummy active region 5A is made equal at all locations of the dummy active region 5A.

### Fourth Embodiment

A semiconductor device according to a fourth embodiment of the present invention is described below with reference to the drawings.

FIG. 5-1 is a plan view showing the construction of a semiconductor device 400 according to the fourth embodiment.

Referring to FIG. 5-1, the first active region 3, dummy active region 5A and second element isolating region 4 that constitute the semiconductor device 400 according to the fourth embodiment will be described.

An island-shaped first active region 3 is provided on the upper face of the silicon substrate, and the periphery thereof is surrounded by the second element isolating region 4. Two dummy active regions 5B are arranged, with interposition of the second element isolating region 4, at both ends of the first active region 3 in the Y direction. Each of these dummy active regions 5B is rectangular and extends in the X direction: thus they are arranged in mutually parallel fashion. The length X1 in the X direction of each of the dummy active regions 5B is the same as the length X2 in the X direction of the rectangular first active region 3 (X1=X2).

Depending on the case, the length X1 in the X direction may be selected to be longer than X2 (X1>X2), or may be selected to be shorter than X2 (X1<X2). However, if X1>X2, even if X1 is increased, the beneficial effect of providing a “dummy active region” is substantially the same as the beneficial effect when X1=X2. On the other hand, if X1<X2, X1 is reduced and if finally substantially X1=0, the beneficial effect of providing a “dummy active region” is lost.

Furthermore, in the construction of a semiconductor device 400 according to the fourth embodiment shown in FIG. 5-1, instead of a mode in which two dummy active regions 5B are provided that are arranged in mutually parallel fashion at both edges in the X direction with respect to the rectangular first active region 3, the construction of a semiconductor device 400-1 according to the fourth embodiment as shown in FIG. 5-2 may be adopted. Specifically, a mode may be selected in which one dummy active region 5B is rectangular and extends in the X direction whereas the other dummy active region 5A is rectangular and extends in the Y direction, these being mutually unified, so as to form an “L”-shaped dummy active region (dummy active region 5B+dummy active region 5A).

If, of the dummy active regions forming the “L” shape shown in FIG. 5-2, the length X1 in the X direction of the rectangular dummy active region 5B portion extending in the X direction is reduced, finally becoming substantially X1=0, the beneficial effect of the provision of a “dummy active region” becomes of the same level as the beneficial effect obtained by providing a rectangular dummy active region 5A extending in the Y direction.

In the semiconductor device 400 according to the fourth embodiment shown in FIG. 5-1, the potential, V_{dummy active region-B-upper} of the upper-edge side dummy active region 5B at the upper edge of the rectangular first active region 3 is the same potential as that within the rectangular dummy active region 5B on this upper-edge side. The bottom of this upper-edge side dummy active region 5B is electrically linked with the bottom of the substrate surrounding the second element isolating region 4 via the residual conductive path at the bottom of the second element isolating region 4, so the potential of the upper-edge side dummy active region 5B, i.e. V_{dummy active region-B-upper}, is the same potential as the potential supplied to the substrate surrounding the second element isolating region 4, i.e. the substrate potential V_{substrate}.

Also, the potential, V_{dummy active region-B-lower}, of the lower-edge side dummy active region 5B provided at the upper edge of the first active region 3 is the same potential as that within the rectangular dummy active region 5B at this lower-edge side. The bottom of this lower-edge side dummy active region 5B is electrically linked with the bottom of the substrate surrounding the second element isolating region 4, through the residual conductive path at the bottom of the second element isolating region 4, so that the potential, V_{dummy active region-B-lower}, of the lower-edge side dummy active region 5B is the same potential as the potential that is supplied to the substrate surrounding the second element isolating region 4 i.e. the substrate potential V_{substrate}.

The bottom of the upper-edge side of the rectangular first active region 3 is electrically linked with the bottom of the upper-edge side dummy active region 5B through the residual conductive path at the bottom of the second element isolating region 4, so that the potential, i.e. V_{active region-bottom-upper}, of the upper-edge side bottom of the rectangular first active region 3 is the same as the potential, V_{dummy active region-B-upper}, of the upper-edge side dummy active region 5B. Likewise, the bottom at the lower-edge side of the rectangular first active region 3 is electrically linked with the bottom of the lower-edge side dummy active region 5B through the residual conductive path at the bottom of the second element isolating region 4, so that the potential, V_{active region-bottom-lower}, of the bottom on the lower-edge side of the rectangular first active region 3 is equal to the potential V_{dummy active region-B-lower} of the lower-edge side dummy active region 5B.

As a result, the potential, V_{active region-bottom} of the bottom of the rectangular first active region 3 is equal to V_{active region-bottom-upper} and V_{active region-bottom-lower}, and is maintained at the same potential as the potential that is supplied to the substrate surrounding the second element isolating region 4 i.e. the substrate potential V_{substrate}.

In the semiconductor device 400-1 according to the fourth embodiment shown in FIG. 5-2, the potential, V_{dummy active region-B-L-shape} of the dummy active region 5B that is formed in an “L” shape, is the same potential in the interior of the “L”-shaped dummy active region 5B. The bottom of this “L”-shaped dummy active region 5B is electrically linked with the bottom of the substrate surrounding the second element isolating region 4 through the residual conductive path at the bottom of the second element isolating region 4 i.e. the potential of the “L”-shaped dummy active region 5B, V_{dummy active region-B-L-shape}, is a potential equal to the potential that is supplied to the substrate surrounding the second element isolating region 4 i.e. the substrate potential V_{substrate}.

As a result, the potential at the bottom of the rectangular first active region 3, i.e. V_{active region-bottom}, is equal to V_{dummy active region-B-L-shape} and is maintained at a potential equal to the potential that is supplied to the substrate surrounding the second element isolating region 4 i.e. the substrate potential V_{substrate}.

Furthermore, in the fourth embodiment, in addition to the mode shown in FIG. 5-1 and the mode shown in FIG. 5-2, a mode may be adopted in which two dummy active regions 5A are provided that are arranged in mutually parallel fashion, at both edges in the Y direction with respect to the rectangular first active region 3. Specifically, in the fourth embodiment, when two dummy active regions are provided, an arrangement may be adopted wherein dummy active regions, corresponding to the dummy active region 5A, that was adopted in the semiconductor device 300 according to the third embodiment as shown in FIG. 4-1, are arranged in mutually parallel fashion at both edges (the right edge and the left edge) in the Y direction with respect to the rectangular first active region 3.

### Fifth Embodiment

A semiconductor device according to a fifth embodiment of the present invention is described below with reference to the drawings.

FIG. 6 is a plan view showing the construction of a semiconductor device 500 according to the fifth embodiment.

Referring to FIG. 6, the first active region 3, a dummy active region 5C and the second element isolating region 4 constituting the semiconductor device 500 according to the fifth embodiment will be described.

An island-shaped first active region 3 is provided at the upper face of the silicon substrate, its periphery being surrounded by the second element isolating region 4. Two portions of a dummy active region 5C are arranged, with the second element isolating region 4 interposed, at both edges in the X direction of the rectangular first active region 3; a remaining one portion of the dummy active region 5C is arranged, with the second element isolating region 4 interposed, at one edge in the Y direction of the rectangular first active region 3. These three portions of the dummy active region 5C are integrated so as to constitute as a whole a “U”-shaped dummy active region 5C.

It should be noted that, in the semiconductor device 500 according to the fifth embodiment shown in FIG. 6, the length Y3 in the Y direction of the two portions of the dummy active region 5C that are arranged at both edges in the X direction of the rectangular first active region 3 is longer than the length Y4 in the Y direction of the rectangular first active region 3 (Y3>Y4).

Depending on the case, the length Y3 in the Y direction may be selected to be equal to Y4 (Y3=Y4), or may be selected to be shorter than Y4 (Y3<Y4). However, when Y3<Y4, Y3 is reduced and the beneficial effect achieved by constituting the dummy active region 5C of a “U” shape, as a whole, provided with two portions of the “dummy active region” that are arranged at both edges in the X direction of the rectangular first active region 3 is progressively reduced. When finally “Y3=0” is reached, the beneficial effect is reduced to the level of the beneficial effect that is obtained in a condition in which a single remaining portion of the dummy active region 5C is arranged at one edge in the Y direction of the rectangular first active region 3.

A mode may also be selected in which, as the three portions that constitute the “U”-shaped dummy active region 5C, two portions are arranged at both edges in the Y direction of the rectangular first active region 3 and the remaining single portion is arranged at one edge in the X direction; these three portions being united.

In the semiconductor device 500 according to the fifth embodiment shown in FIG. 6, the potential of the dummy active region 5C that is formed in a “U” shape, i.e. V_{dummy active region-C}, is the same potential in the interior of the “U”-shaped dummy active region 5C. The bottom of this “U”-shaped dummy active region 5C is electrically linked with the bottom of the substrate that surrounds the second element isolating region 4, with interposition of the residual conductive path at the bottom of the second element isolating region 4, so the potential of the “U”-shaped dummy active region 5C, i.e. V_{dummy active region-C}, is a potential that is equal to the potential that is supplied to the substrate surrounding the second element isolating region 4 i.e. the substrate potential V_{substrate}.

As a result, the potential, V_{active region-bottom}, of the bottom of the rectangular first active region 3, like V_{dummy active region-C}, is maintained at the same potential as the potential, substrate potential V_{substrate}, that is supplied to the substrate surrounding the second element isolating region 4.

When the “U”-shaped dummy active region 5C shown in FIG. 6 is provided on the P type silicon substrate, a mode is selected in which no P type impurity diffusion layer is provided in the surface thereof; however, a mode could also be selected in which a P type impurity diffusion layer is provided in the surface.

However, if a P type impurity diffusion layer is provided on the surface, if a potential equal to the substrate potential V_{substrate} is applied to this P type impurity diffusion layer through the contact plug, the “U”-shaped dummy active region 5C is transformed to a “U”-shaped “second active region”. If a “U”-shaped “second active region” is provided instead of the “U”-shaped dummy active region 5C, the “beneficial effect” produced by providing a “dummy active region” is lost.

In contrast, if, albeit a contact plug is formed that is capable of applying potential equal to the substrate potential V_{substrate} to the surface P type impurity diffusion layer, application of such potential is not performed, the “U”-shaped dummy active region 5C will not be transformed to a “U”-shaped “second active region”. Consequently, the “beneficial effect” of providing a “U”-shaped dummy active region 5C will not be lost. Consequently, when a “U”-shaped dummy active region 5C is provided on the P type silicon substrate, the same beneficial effect is exhibited as in the case where a mode is selected in which no P type impurity diffusion layer is provided in the surface.

### Sixth Embodiment

A semiconductor device according to a sixth embodiment of the present invention is described below with reference to the drawings.

FIG. 7 is a plan view showing the layout of a semiconductor device 600 according to the sixth embodiment.

Referring to FIG. 7, the first active region 3, a dummy active region 5D and the second element isolating region 4 constituting the semiconductor device 500 according to the fifth embodiment will be described.

An island-shaped first active region 3 is provided at the upper face of the silicon substrate, its periphery being surrounded by the second element isolating region 4. Two portions of a dummy active region 5D are arranged, with the second element isolating region 4 interposed, at both edges in the X direction of the rectangular first active region 3; the remaining two portions of the dummy active region 5D are arranged, with the second element isolating region 4 interposed, at both edges in the X direction of the rectangular first active region 3. These four portions of the dummy active region 5D, as a whole, are arranged surrounding the periphery of the rectangular first active region 3, with the second element isolating region 4 interposed.

Provided that, as a whole, an arrangement is adopted in which a plurality of portions constituting the dummy active region 5D surrounds the periphery of the rectangular first active region 3, with interposition of the second element isolating region 4, the plural number of portions constituting the dummy active region 5D could be selected to be a number of more than four but for example no more than six: as an optimum arrangement, a total of five or more such portions could be provided. For example, an arrangement could be adopted in which a single portion of the dummy active region 5D arranged at one edge in the X direction of the first active region 3 is divided into two and the resulting portions are arranged on a single virtual straight line in the Y direction; the first active region 3 thus being surrounded by a dummy active region 5D constituted by a total of five portions, with interposition of the second element isolating region 4.

In the semiconductor device 600 according to the sixth embodiment shown in FIG. 7, the potential, V_{dummy active region-C} of the dummy active region 5D divided into four portions has the same potential in the interior of the individual portions of the rectangular dummy active region 5D. The bottoms of the various portions of this dummy active region 5D are electrically linked with the bottom of the substrate that surrounds the second element isolating region 4, with interposition of the residual conductive path at the bottom of the second element isolating region 4, so the potential of the various portions of the rectangular dummy active region 5D, i.e. V_{dummy active region-D}, is a potential that is equal to the potential that is supplied to the substrate surrounding the second element isolating region 4 i.e. the substrate potential V_{substrate}.

As a result, the potential, V_{active region-bottom}, of the bottom of the rectangular first active region 3, like V_{dummy active region-D}, is maintained at the same potential as the potential, substrate potential V_{substrate}, that is supplied to the substrate surrounding the second element isolating region 4.

### Seventh Embodiment

A semiconductor device according to a seventh embodiment of the present invention is described below with reference to the drawings.

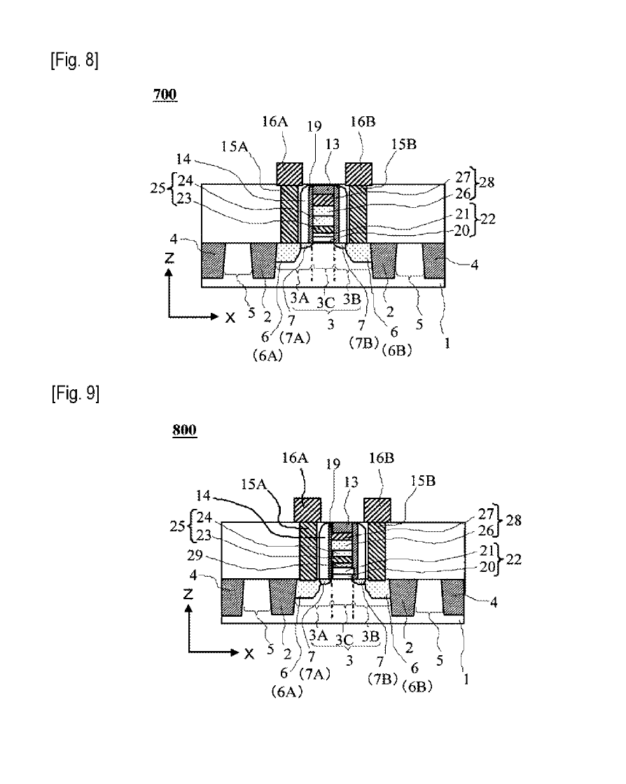

FIG. 8 is a cross-sectional view showing the layout of a semiconductor device 700 according to the seventh embodiment.

Referring to FIG. 8, an example of the construction of a semiconductor device 700 according to a seventh embodiment wherein the first active region 3, the dummy active region 5 and the second element isolating region 4 are provided in an N type planar MIS (Metal Insulator Semiconductor) transistor structure in which a gate insulating film 22 provided with a high dielectric constant insulating film (high-k film) 21 is adopted is described. The cross-sectional plane in FIG. 8, like that in FIG. 2, corresponds to the A-A′ cross-sectional plane in the planar arrangement shown in FIG. 1. Also, the high dielectric constant insulating film is a film of higher dielectric constant than the silicon oxide film (SiO₂).

In the semiconductor device 700 according to the seventh embodiment shown in FIG. 8, a gate insulating film 22 is constituted by an insulating film 20 made of silicon oxide film (SiO₂) that covers the upper surface of the first active region 3C, and a high dielectric constant insulating film 21 made of hafnium oxide (HfO₂) that covers the upper surface of the insulating film 20. Also, a gate electrode 25 is constituted by a metal film 23 made of titanium nitride (TiN) that covers the upper surface of the high dielectric constant insulating film 21, and a first polysilicon film 24 that covers the upper surface of the metal film 23. Consequently, the semiconductor device 700 according to the seventh embodiment is an N type planar MISFET employing an HKMG construction, comprising a high dielectric constant gate oxide film and a metal gate electrode, formed on a P type semiconductor substrate.

When this N type planar MISFET is constructed, an LDD structure is selected comprising an impurity diffusion layer 6A provided on one of the source/drain regions provided on the first active region 3A and an impurity diffusion layer 6B constituting the other of the source/drain regions provided on the first active region 3B; in addition there are provided LDD regions 7A and 7B.

As the high dielectric constant insulating film 21, there may be employed a film containing at least one high dielectric constant insulating material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃. Also, nitrogen may be included in the high dielectric constant insulating film.

In addition, instead of titanium nitride (TiN), as the metal film 23, there may be employed a layer containing at least one element selected from the group consisting of Ti, W, Ta, Ru and Al.

On the upper surface of the first polysilicon film 24, there is provided a conductive layer 28 constituted of a second polysilicon film 26 and a tungsten (W) film 27; the upper surface of the tungsten film 27 is covered with a mask film 13. In the semiconductor device 700 according to the seventh embodiment, the gate insulating film 22 of HKMG construction and the gate electrode, and the conductive film 28 and the mask film 13 sidewalls are covered by a spacer film 19 and a sidewall insulating film 14.

By employing the spacer film 19 and the sidewall insulating film 14, the LDD regions 7A and 7B and the impurity diffusion layers 6A and 6B are respectively formed in self-aligned fashion.

In the semiconductor device 700 according to the seventh embodiment shown in FIG. 8, a construction is selected in which no diffusion layer is provided in the dummy active region 5.

### Eighth Embodiment

A semiconductor device according to an eighth embodiment of the present invention is described below with reference to the drawings.

FIG. 9 is a cross-sectional view showing the layout of a semiconductor device 800 according to an eighth embodiment.

Referring to FIG. 9, an example of the construction of a semiconductor device 800 according to an eighth embodiment wherein the first active region 3, the dummy active region 5 and the second element isolating region 4 are provided in a P type planar MIS (Metal Insulator Semiconductor) transistor structure in which a gate insulating film 22 provided with a high dielectric constant insulating film (high-k film) 21 is adopted is described. The cross-sectional plane in FIG. 9, like that in FIG. 2, corresponds to the A-A′ cross-sectional plane in the planar arrangement shown in FIG. 1. It should be noted that repetition of aspects of the description and drawings that are shared with the seventh embodiment is avoided and the description thus focuses on the differences with respect to the seventh embodiment.

The semiconductor device 800 according to the eighth embodiment is manufactured on an N type well region formed in a P type semiconductor substrate, in order to constitute a P type planar MISFET.

In the semiconductor device 800 according to the eighth embodiment shown in FIG. 9, a gate insulating film 22 is constituted by an insulating film 20 made of silicon oxide film (SiO₂) that covers the upper surface of the first active region 3C, and a high dielectric constant insulating film 21 made of hafnium oxide (HfO₂) that covers the upper surface of the insulating film 20. In addition, a cap film 29 is provided, made of aluminum oxide (Al₂O₃), that covers the upper surface of the high dielectric constant insulating film 21. Also, a gate electrode 25 is constituted by a metal film 23 made of titanium nitride (TiN) that covers the upper surface of the cap film 29 and a first polysilicon film 24 that covers the upper surface of the metal film 23. Consequently, the semiconductor device 800 according to the eighth embodiment is a P type planar MISFET employing an HKMG construction, comprising a high dielectric constant gate oxide film and a metal gate electrode, formed on an N type well region.

When this P type planar MISFET is constructed, an LDD structure is selected comprising an impurity diffusion layer 6A provided on one of the source/drain regions provided on the first active region 3A and an impurity diffusion layer 6B constituting the other of the source/drain regions provided on the first active region 3B; in addition there are provided LDD regions 7A and 7B.

### Ninth Embodiment

A semiconductor device according to a ninth embodiment of the present invention is described below with reference to the drawings.

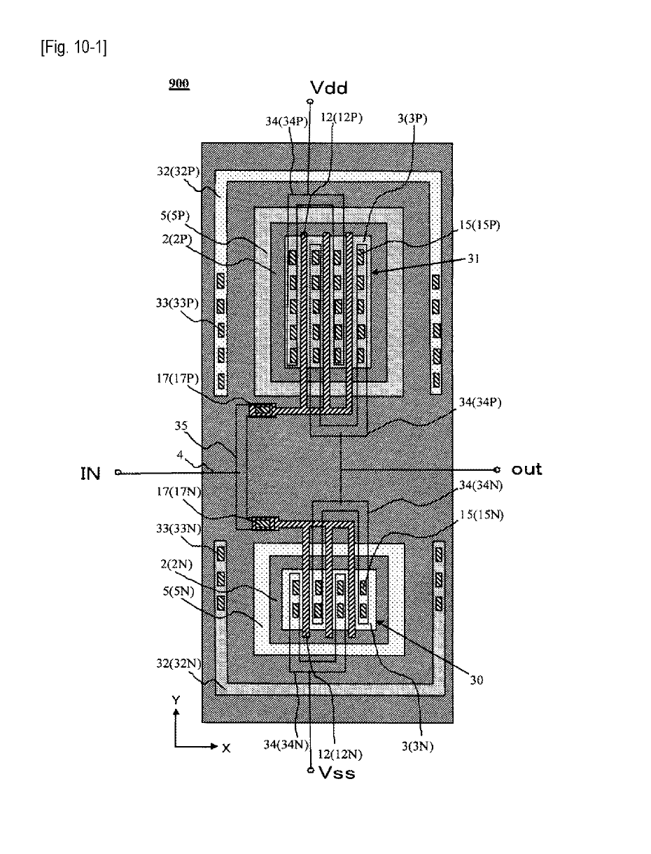

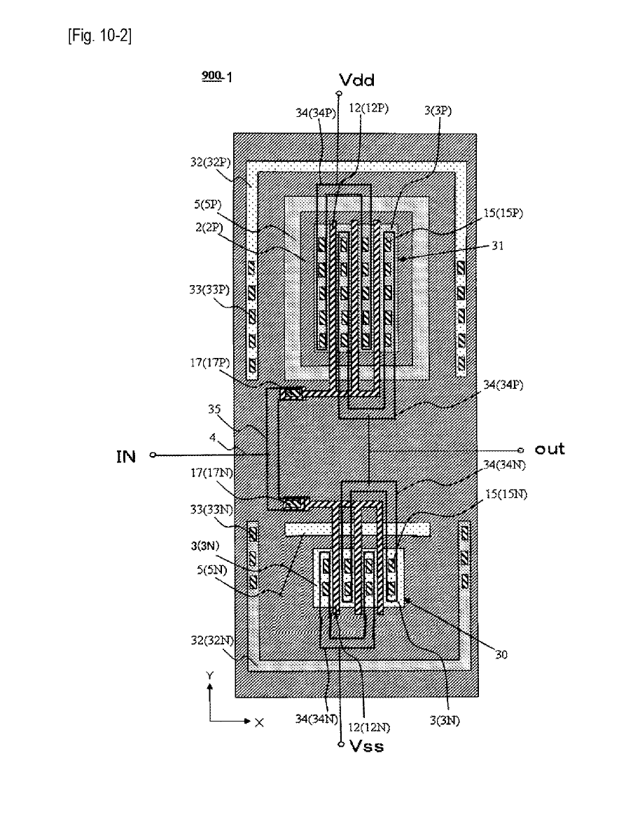

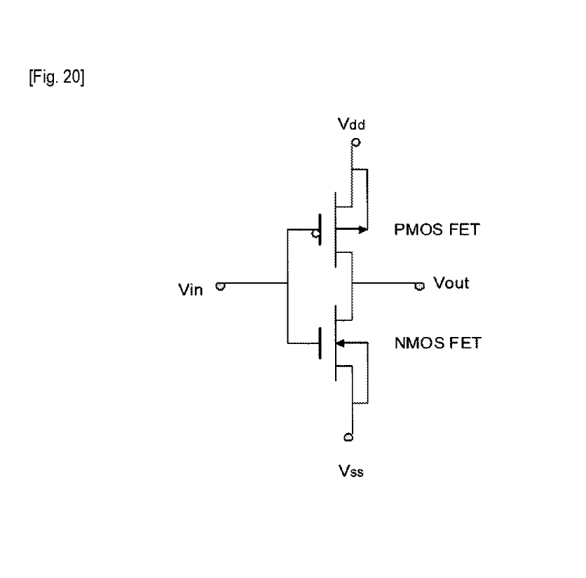

FIG. 10-1 is a plan view showing the layout of a semiconductor device 900 according to the ninth embodiment. The semiconductor device 900 according to the ninth embodiment shown in FIG. 10-1 constitutes a CMOS (Complementary MOS) inverter represented by the circuit shown in FIG. 20.

Referring to FIG. 10-1, the construction of the semiconductor device 800 according to the ninth embodiment and the construction of a CMOS inverter comprising a first transistor 30 constituted by an N type MOS transistor and a second transistor 31 constituted by a P type MOS transistor will be described. The N type MOS transistor constituted by the first transistor 30 is formed in a P type well region and the P type MOS transistor constituted by the second transistor 31 is formed in an N type well region. The first transistor 30 and the second transistor 31 shown in FIG. 10-1 have a different conduction type and number of planar-type MOSFETs arranged in the first active region 3, compared with the semiconductor device 100 according to the first embodiment shown in FIG. 1, but the structural elements represented by the first active region 3, the first element isolating region 2, dummy active region 5, and second element isolating region 4 are essentially shared with the semiconductor device 100 according to the first embodiment. The following description will focus on the constructional differences between the first transistor 30 and second transistor 31 shown in FIG. 10-1 and the semiconductor device 100 shown in FIG. 1.

In the first transistor 30 constituting the N type MOS transistor formed in the P type well region, the ring-shaped dummy active region 5 (5N) and first active region 3 (3N) are separated by surrounding the periphery of the first active region 3 (3N) by the formation of a ring-shaped first element isolating region 2 (2N). The second element isolating region 4 is provided so as to be contiguous with the rectangular periphery of the ring-shaped dummy active region 5 (5N) and so as to surround this. Also, a “U”-shaped second active region 32 (32N) is formed in a mode wherein the periphery thereof is surrounded by the second element isolating region 4. The “U”-shaped second active region 32 (32N) is arranged at three edges of the rectangular periphery of the ring-shaped dummy active region 5 (5N), with interposition of the second element isolating region 4. Specifically, the “U”-shaped second active region 32 (32N) is arranged at the two edges in the X direction of the dummy active region 5 (5N) having a rectangular periphery, and at one edge in the Y direction thereof, with interposition of the second element isolating region 4. No second active region 32 (32N) is arranged at the other edge side in the Y direction of the dummy active region 5 (5N) having a rectangular periphery.

In the “U”-shaped second active region 32 (32N) that is formed in the P type well region, a P type impurity diffusion layer is provided in the surface thereof and a third contact plug 33 (33N) is provided on this P type impurity diffusion layer. P type well potential, V_{p-well}, is applied to the “U”-shaped second active region 32 (32N) through this third contact plug 33 (33N). The P type well potential V_{p-well}, is selected by V_{SS}. Consequently, the entire “U”-shaped second active region 32 (32N) is maintained at the P type well potential, V_{p-well}=V_{SS}.

Depending on the case, in regard to the “U”-shaped second active region 32 (32N) that is formed in the P type well region, an N type impurity diffusion layer could be provided in the surface thereof instead of the P type impurity diffusion layer. When an N type impurity diffusion layer is provided in the surface, a third contact plug 33 (33N) is provided on this N type impurity diffusion layer. In this case, a pN junction is formed in the “U”-shaped second active region 32 (32N), by the under-layer P type well region (p layer) and the N type impurity diffusion layer (N layer) at the surface, and a depletion layer is formed at the corresponding portion of the under-layer P type well region (p layer). The P type well region is formed on the P type semiconductor substrate and the substrate potential V_{substrate} is applied to this P type semiconductor substrate. As a result of the selection of the substrate potential V_{substrate} as V_{substrate}=V_{SS}, when P type well potential, V_{p-well}=V_{SS} is applied to the surface N type impurity diffusion layer (N layer) through the third contact plug 33 (33N), the potential V_{p-well} of the entire “U”-shaped second active region 32 (32N) is maintained at the P type well potential, V_{p-well}=V_{SS}.

In the case of the first transistor 30 in the semiconductor device 900 according to the ninth embodiment shown in FIG. 10-1, an N type impurity diffusion layer is formed in the surface of the dummy active region 5 (5N) formed in the P type well region. In the ring-shaped dummy active region 5 (5N), a pN junction is formed by the under-layer P type well region (p layer) and the surface N-type impurity diffusion layer (N layer), and a depletion layer is formed in the corresponding portion of the under-layer P type well region (p layer).

The gate electrode 12 (12N) spans a portion “one side in the Y direction” of the ring-shaped dummy active region 5 (5N), where no second active region 32 (32N) is provided. Specifically, an HKMG structure is formed at the surface of the portion “one side in the Y direction” of the dummy active region 5 (5N), and at both sides thereof, LDD regions 7A and 7B, and N type impurity diffusion layers 6A and 6B, are respectively formed in a self-aligned fashion. These N type impurity diffusion layers at both edges are electrically linked by the N type impurity diffusion layer (N layer) provided at the surface of the ring-shaped dummy active region 5 (5N), and so are at the same potential. Consequently, the potential V_{p-well} of the under-layer P type well region (p layer) of the ring-shaped dummy active region 5 (5N) is maintained at the P type well potential V_{p-well}=V_{SS}.

In the case of the first transistor 30, a P type impurity diffusion layer can also be formed instead of the N type impurity diffusion layer at the surface of the dummy active region 5 (5N) formed in the P type well region, and a P type well condition could also be produced without forming an impurity diffusion layer. In this case also, the overall potential V_{p-well} of the under-layer P type well region (p layer) of the ring-shaped dummy active region 5 (5N) is the same potential and is maintained at the P type well potential V_{p-well}=V_{SSs}.

In the case of the first transistor 30, three N type MOSFETs are formed in the first active region 3 (3N), but the three gate electrodes 12 (12N) thereof in the second element isolating region 4 are collected into a single electrode and connected with a fourth wiring 35 through the second contact plug 17 (17N). The two source electrodes are respectively connected with a single third wiring 34 (34N) through the first contact plug 15 (15N) and likewise the two drain electrodes are respectively connected through the first contact plug 15 (15N) with another single third wiring 34 (34N). One of these two third wirings 34 (34N) is connected with the ground terminal: V_{SS}, while the other is connected with an output signal terminal: OUT.

Also in the second transistor 31, which is constituted by a P type MOS transistor formed in the N type well region, there are likewise arranged: the first active region 3 (3P); the first element isolating region 2 (2P); the dummy active region 5 (5P); a second active region 32 (32P); a third contact plug 33 (33P); a first contact plug 15 (15P); and a third wiring 34 (34P). In the second transistor 31 shown in FIG. 10-1, the ring-shaped dummy active region 5 (5P) and the first active region 3 (3P) are isolated by surrounding the periphery of the first active region 3 (3P) by forming a ring-shaped first element isolating region 2 (2P). The second element isolating region 4 is arranged contiguous with and so as to surround the rectangular periphery of the ring-shaped dummy active region 5 (5P). Also, the “U”-shaped second active region 32 (32P) is formed in a mode wherein its periphery is surrounded by the second element isolating region 4. Of the rectangular periphery of the ring-shaped dummy active region 5 (5P), the “U”-shaped second active region 32 (32P) is arranged at three edges thereof, with interposition of the second element isolating region 4. Specifically, the “U”-shaped second active region 32 (32P) is arranged at both edges in the X direction of the dummy active region 5 (5P) having a rectangular periphery, and at one edge in the Y direction thereof, with interposition of the second element isolating region 4. No second active region 32 (32P) is arranged at the other edge in the Y direction of the dummy active region 5 (5P) having a rectangular periphery.

The “U”-shaped second active region 32 (32P) that is formed in the N type well region (n layer) is provided at its surface with an N type impurity diffusion layer and a third contact plug 33 (33P) is provided on this N type impurity diffusion layer. N type well potential, V_{n-well}, is applied to this “U”-shaped second active region 32 (32P) through this third contact plug 33 (33P). The N type well potential, V_{n-well}, is selected as V_{dd}. Consequently, the entire “U”-shaped second active region 32 (32P) is maintained at the N type well potential, V_{n-well}=K_{dd}.

Depending on the case, the “U”-shaped second active region 32 (32P) that is formed in the N type well region may be provided with a P type impurity diffusion layer at its surface, instead of the N type impurity diffusion layer. When a P type impurity diffusion layer is provided at the surface, a third contact plug 33 (33P) is provided on this P type impurity diffusion layer. In this case, a Pn junction is formed in the “U”-shaped second active region 32 (32P) by the under-layer n type well region (n layer) and the surface P-type impurity diffusion layer (P layer), and a depletion layer is formed in the corresponding portion of the under-layer n type well region (n layer). The N type well region (n layer) is formed on the P type semiconductor substrate: separately, N type well potential, V_{n-well}, is applied to the N type well region (n layer). The N type well potential, V_{n-well}, is selected as V_{dd}. When the N type well potential, V_{n-well}=V_{dd}, is applied to the surface P type impurity diffusion layer (P layer) through the third contact plug 33 (33P), the potential V_{n-well} of the “U”-shaped second active region 32 (32P) as a whole is maintained at the N well potential V_{n-well}=V_{dd}.

In the second transistor 31, an N type impurity diffusion layer may also be formed, instead of the P type impurity diffusion layer, at the surface of the dummy active region 5 (5P) that is formed on the N type well region; it is also possible to produce an N type well condition without forming an impurity diffusion layer. In this case also, the potential V_{n-well} of the under-layer N type well region (n layer) of the ring-shaped dummy active region 5 (5P) is entirely at the same potential and is maintained at the N type well potential V_{n-well}=V_{dd}.

In the second transistor 31, three P type MOSFETs are formed in the first active region 3 (3P), but, in the second element isolating region 4, the three gate electrodes 12 (12P) thereof are collected into a single electrode, which is connected with a fourth wiring 35 through a second contact plug 17 (17P). The two source electrodes are respectively connected with a single third wiring 34 (34P) through the first contact plug 15 (15P); likewise, the two drain electrodes are respectively connected with another single third wiring 34 (34P), through the first contact plug 15 (15P). One of the two third wirings 34 (34P) is connected with the power source terminal: V_{dd}, while the other is connected with the output signal terminal: OUT.

The fourth wiring 35 is connected with an input signal terminal: IN. Consequently, the semiconductor device 900 according to the ninth embodiment shown in FIG. 10-1 comprises an input signal terminal: IN, an output signal terminal: OUT, a power source terminal: V_{dd}, and an earth terminal: V_{SS}; the CMOS inverter circuit illustrated in FIG. 20 is thereby constituted.

FIG. 10-2 is a plan view showing the layout of a semiconductor device 900-1 according to the ninth embodiment.

The semiconductor device 900-1 according to the ninth embodiment shown in FIG. 10-2 also constitutes a CMOS (Complementary MOS) inverter as represented by the circuit shown in FIG. 20.

Referring to FIG. 10-2, the construction of a semiconductor device 800-1 according to the ninth embodiment, specifically, the construction of a CMOS inverter comprising a first transistor 30 constituted by an N type MOS transistor and a second transistor 31 constituted by a P type MOS transistor, will be described.

The second transistor 31 constituted by a P type MOS transistor shown in FIG. 10-2 and the second transistor 31 constituted by a P type MOS transistor shown in FIG. 10-1 have the same construction.

The differences between the first transistor 30 constituted by an N type MOS transistor shown in FIG. 10-2 and the first transistor 30 constituted by an N type MOS transistor shown in FIG. 10-1 will now be described.

In the first transistor 30 shown in FIG. 10-2, the periphery of the rectangular first active region 3 (3N) is surrounded by the second element isolating region 4. A single dummy active region 5 (5N) is arranged, with interposition of the second element isolating region 4, at one edge in the Y direction of the first active region 3 (3N).

Consequently, the single dummy active region 5 (5N) and “U”-shaped second active region 32 (32N) are formed, with interposition of the second element isolating region 4, so as to surround the periphery of the rectangular first active region 3 (3N).

In the first transistor 30 shown in FIG. 10-2, an N type impurity diffusion layer is formed at the surface of the single dummy active region 5 (5N) that is arranged in the P type well region. A pN junction is formed by the under-layer P type well region (p layer) and the surface N type impurity diffusion layer (N layer); also a depletion region is formed in the corresponding portion of the under-layer P type well region (p layer). The entire single dummy active region 5 (5N) is substantially at the same potential. In the single dummy active region 5 (5N), the potential of the under-layer P type well region (p layer) thereof is the P type well potential i.e. V_{p-well}=V_{SS}. Consequently, in the entire single dummy active region 5 (5N), the potential of this under-layer P type well region (p layer) is maintained at the P type well potential i.e. V_{p-well}=V_{SS}.

Also, in the first transistor 30 shown in FIG. 10-2, in the surface of the “U”-shaped second active region 32 (32N), there is formed a P type impurity diffusion layer and a third contact plug 33 (33N) is provided on this P type impurity diffusion layer. The P type well potential, i.e. V_{p-well}, is applied to this “U”-shaped second active region 32 (32N) through this third contact plug 33 (33N). The P type well potential V_{p-well} is selected as V_{SS}. Consequently, the entire “U”-shaped second active region 32 (32N) is maintained at the P well potential i.e. V_{p-well}=V_{SS}.

### Other Embodiments

Examples of “other embodiments” of the present invention are given below.

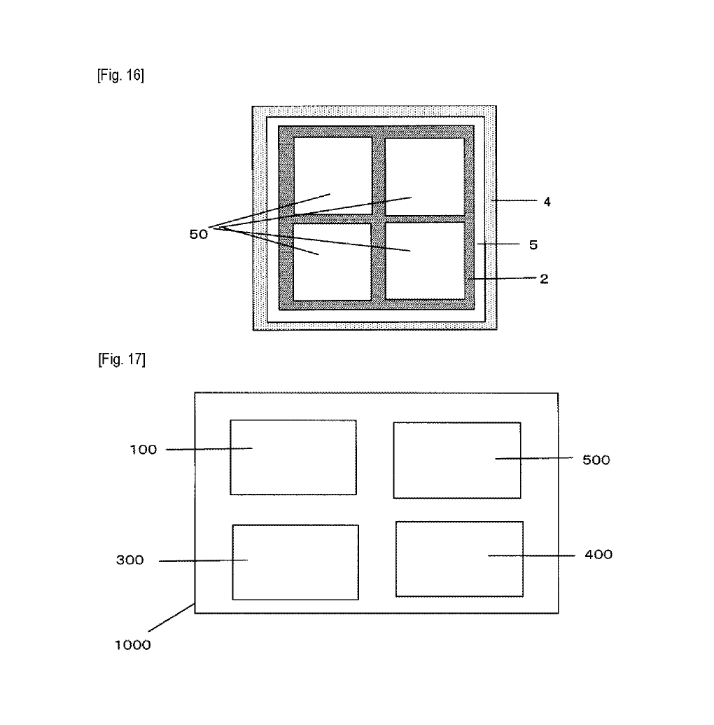

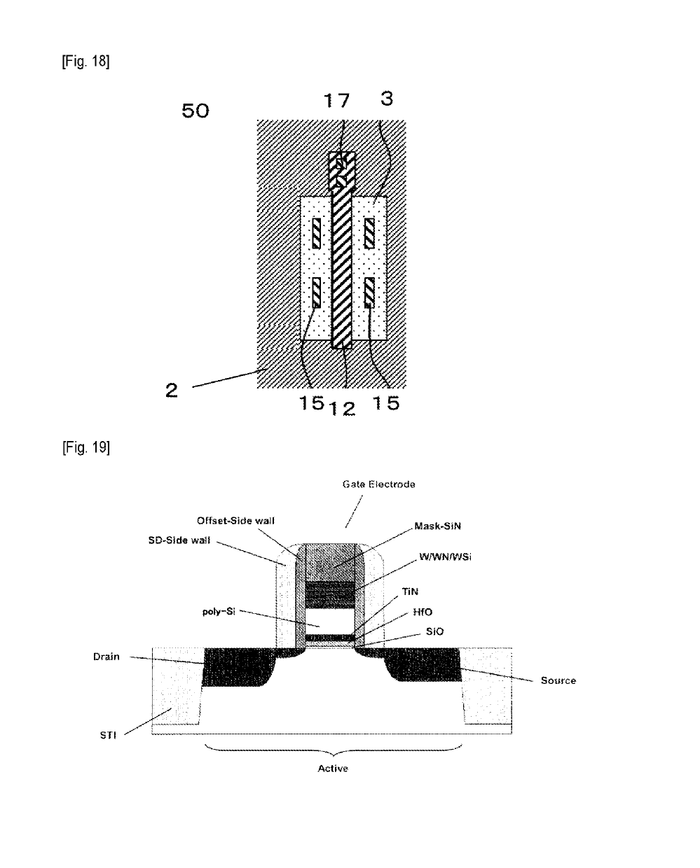

As shown in FIG. 16, in the single dummy active region 5 there may be provided a plurality of transistors 50 (i.e. transistors 50 not having a dummy active region shown in FIG. 18; this portion corresponds to the MOSFET of construction set out in for example Patent Reference 4) surrounding the foregoing on four sides.

In the semiconductor devices (transistors) 50 shown in FIG. 18, a MOSFET is arranged in the first active region 3 surrounded by the first element isolating region 2; however, in the mode shown in FIG. 16, mutually between the individual semiconductor devices (transistors) 50, and also at the periphery of the entire plurality of semiconductor devices (transistors) 50 that are there provided, there is provided a first element isolating region 2, and this is united with the first element isolating regions 2 that are individually provided at the individual semiconductor devices (transistors) 50.

In the embodiment shown in FIG. 16, a single loop-shaped dummy active region 5 is provided surrounding on four sides the first element isolating region 2 that is arranged contiguous with the plurality of transistors 50.

Respective “L”-shaped dummy active regions 5 are arranged with respect to the individual semiconductor devices (transistors) 50 and a single loop-shaped dummy active region 5 surrounding these from four directions is constituted by mutual linkage of these “L”-shaped dummy active regions 5. A single loop-shaped second element isolating region 4 is provided that is contiguous with and surrounds this loop-shaped dummy active region 5 from four directions.

Also, the potential V_{dummy active region} of the loop-shaped dummy active region 5 is the same potential. The bottom of the first active region 3 of the individual semiconductor devices (transistors) 50 is electrically connected with the bottom of the dummy active region 5 through the residual conductive path at the bottom of the first element isolating region 2. As a result, the potential V_{first active region-bottom} at the bottom of the first active region 3 of the individual semiconductor devices (transistors) 50 is maintained at the same potential as the potential V_{dummy active region-bottom} at the bottom of the loop-shaped dummy active region 5.

In the embodiment shown in FIG. 16, a construction is adopted in which respective semiconductor devices (transistors) are arranged in four zones demarcated by a “ [symbol] ”-shaped first element isolating region 2. For the semiconductor devices (transistors) arranged in the individual zones, it would also be possible to adopt a construction in which, apart from the semiconductor devices (transistors) 50 having the construction shown by way of example in FIG. 18, there is provided a second active region 32 in the individual first element isolating regions 2, arranged so as to surround the first active region 3 of each semiconductor device (transistor). For example, a mode may be selected in which a “U”-shaped second active region 32 is provided in respect of a rectangular first active region 3, and, in respect of the remaining edge, dummy active regions are arranged sandwiching the first element isolating region 2, a construction of the loop-shaped dummy active region 5 being adopted wherein the dummy active regions that are arranged at the semiconductor devices (transistors) arranged in each zone are united. In other words, for the semiconductor devices (transistors) that are respectively provided in the four zones demarcated in the “ [symbol] ”-shaped first element isolating region 2, it would be possible to provide a second active region 32 in addition to the first active region 3. However, it is more desirable to achieve the “beneficial effect” attained by producing a loop-shaped dummy active region 5: this can be done by adopting a construction in which no dummy active region is provided, at least in the individual zones.

Furthermore, a construction could be adopted in which for example a mode is selected wherein an “L”-shaped second active region 32 is provided in respect of the rectangular first active region 3, and, in respect of the remaining two edges, an “L”-shaped dummy active region is arranged sandwiching the first element isolating region 2: in this case, the “L”-shaped dummy active regions arranged in respect of the semiconductor devices (transistors) positioned in each zone can be united to form a single loop-shaped dummy active region 5.

Depending on the case, in the semiconductor devices (transistors) arranged in each zone demarcated by the first “ [symbol] ”-shaped element isolating region 2, when providing the second active region 32 in the individual first element isolating regions 2 arranged so as to surround the first active region 3 of the individual semiconductor devices (transistors), a loop-shaped second active region 32 may also be employed.

There is no restriction to the mode in which, as shown in FIG. 17, in a single chip 1000, a single semiconductor device of the construction shown in FIG. 4-1, FIG. 4-2, FIG. 5-1, FIG. 5-2, FIG. 6 or FIG. 7 is arranged, and it would be possible to arrange a plurality of types of semiconductor devices selected from the group consisting of semiconductor devices 100, semiconductor devices 200, semiconductor devices 300, semiconductor devices 300-1, semiconductor devices 400, semiconductor devices 400-1, semiconductor devices 500 or semiconductor devices 600 therein.

(Example of Confirmation of Beneficial Effect Achieved by Adoption of the Dummy Active Region According to the Present Invention)

FIG. 11 is a graph showing the results obtained by measuring the dependence of the threshold voltage Vt on the gate width W in respect of an N type planar MOS transistor employing a high dielectric constant gate oxide film using a high dielectric constant insulating film. In FIG. 11, a comparison is plotted of the measurement results (dummy active region present) in a semiconductor device in which a “dummy active region” is arranged contiguous with the first element isolating region surrounding the first active region, and the measurement results (dummy active region absent) in a semiconductor device in which no “dummy active region” is provided.

Extrapolating the measurement results (dummy active region present) in regard to a semiconductor device arranged in the “dummy active region”, when the gate width W reaches W=20 μm, it may be inferred that the threshold voltage Vt thereof would become substantially equal to the threshold voltage Vt at W=20 μm in the measurement results (dummy active region absent) in the case of a semiconductor device where no “dummy active region” is provided. Also, extrapolating the measurement results (dummy active region present) in regard to a semiconductor device in which a “dummy active region” is provided, when the gate width W reaches W=0.2 μm, it may be inferred that the threshold voltage Vt thereof would become substantially equal to the threshold voltage Vt at W=0.2 μm in the measurement results (dummy active region absent) in the case of a semiconductor device where no “dummy active region” is provided.

The difference in the threshold voltage Vt (W) at a gate width W and the amount of shift of the threshold voltage, referred to as threshold voltage Vt (W=20 μm) at a gate width W of W=20 μm i.e. ΔVt(W)={Vt(W)−Vt (W=20 μm)} will now be considered. Although, as the gate width W decreases from 20 μm to 0.2 μm the amount of shift of the threshold voltage: ΔVt(W)={Vt(W)−Vt (W=20 μm)} decreases, in the case of a semiconductor device wherein a “dummy active region” is provided, the amount of this shift is smaller by an order of magnitude than in the case of a semiconductor device where no “dummy active region” is provided. By the provision of the “dummy active region”, increase in the amount of shift of the threshold voltage resulting from reduction in the gate width W is greatly suppressed.

Consequently, with the construction of the semiconductor device according to the first embodiment or the construction of the semiconductor device according to the ninth embodiment, in which a “dummy active region” is provided, the rise (shift) in the threshold voltage Vt is suppressed and stable operation of the semiconductor device can be achieved.

We shall now refer to FIG. 11, which shows a comparison of the measurement results (dummy active region present) in the case of a semiconductor device where a “dummy active region” is provided with the measurement results in the case of a semiconductor device where no “dummy active region” is provided (dummy active region absent). It can be seen that, in the range where the gate width W is 0.1 μm to 20 μm, the amount of shift: ΔVt(W) of the threshold voltage Vt in a semiconductor device where a “dummy active region” is provided cannot exceed the amount of shift: ΔVt(W) of the threshold voltage Vt in a semiconductor device where no “dummy active region” is provided. Also, in the range where the gate width W is 0.2 μm to 10 μm, the amount of shift: ΔVt(W) of the threshold voltage Vt in a semiconductor device where a “dummy active region” is provided is smaller than the amount of shift: ΔVt(W) of the threshold voltage Vt in a semiconductor device where no “dummy active region” is provided. In particular, it can be seen that, in the range of gate width W of 0.5 μm to 10 μm, there is an outstanding benefit in terms of reduction in the shift in the amount of the threshold voltage Vt.

It should be noted that the comparison results shown in FIG. 11 are both for a planar-type MOSFET of gate length L=0.06 μm, for the case of a semiconductor device (dummy active region present) wherein a “dummy active region” is provided, and a semiconductor device (dummy active region absent) wherein no “dummy active region” is provided. Also, a silicon nitride film that covers the side face of the gate pattern is employed as a spacer film 19 and a silicon oxide film that covers the spacer film 19 of the gate pattern side face, constituted by the silicon nitride film, is employed as a sidewall insulating film 14. Since the sidewall insulating film 14 is formed by a silicon oxide film, a shift in the threshold voltage Vt is produced, caused by increase in the EOT of the gate insulating film and induction of negative fixed charge in the gate insulating film. The amount of the shift of the threshold voltage Vt caused by the increase in the EOT of the gate insulating film and induction of the negative fixed charge in the gate insulating film shows substantially no dependence on the gate width W. Consequently, it is concluded that the difference in the amount of shift of the threshold voltage Vt dependent on the gate width W that is found between the case of a semiconductor device (dummy active region present) wherein a “dummy active region” is provided, and a semiconductor device (dummy active region absent) wherein no “dummy active region” is provided that is seen in the comparison results shown in FIG. 11 is caused by some factor other than increase in the EOT of the gate insulating film and induction of negative fixed charge in the gate insulating film. In other words, even though a shift in the threshold voltage Vt caused by increase in the EOT of the gate insulating film and induction of negative fixed charge in the gate insulating film can be avoided by manufacturing the sidewall inserting film 14 using an aluminum oxide film instead of a silicon oxide film, the beneficial effect of reduction in the amount of shift of the threshold voltage Vt occurring in dependence on the gate width W is achieved by the provision of a “dummy active region”.

Consequently, the beneficial effect according to the present invention of the provision of a “dummy active region” can be utilized for effectively suppressing the amount of shift of the threshold voltage Vt when a range of gate width W of 0.1 μm to 20 μm, preferably a range of 0.2 μm to 10 μm, is selected. In this regard, it is desirable to select the gate length L of the “transistor having a high dielectric constant gate insulating film and gate electrode and diffusion layer”, in particular, a planar-type MOSFET, that is manufactured in the first active region, in the range 0.02 μm to 1 μm.

Preferably, when verifying the effect obtained by the provision of a “dummy active region” according to the present invention, the gate length L of the planar-type MOSFET that is thus manufactured is selected in the range of example 0.06 μm to 1 μm.

Typically, the length L and gate width W in a planar-type MOSFET are selected so as to satisfy at least the relationship W>L. Consequently, it is desirable to select, from the above selection range of the gate length L and the above selection range of the gate width W, a gate length L and gate width W so as to satisfy at least the relationship W>L, preferably the relationship W≧10×L.

(Process of Manufacturing a Semiconductor Device 100 According to the First Embodiment)

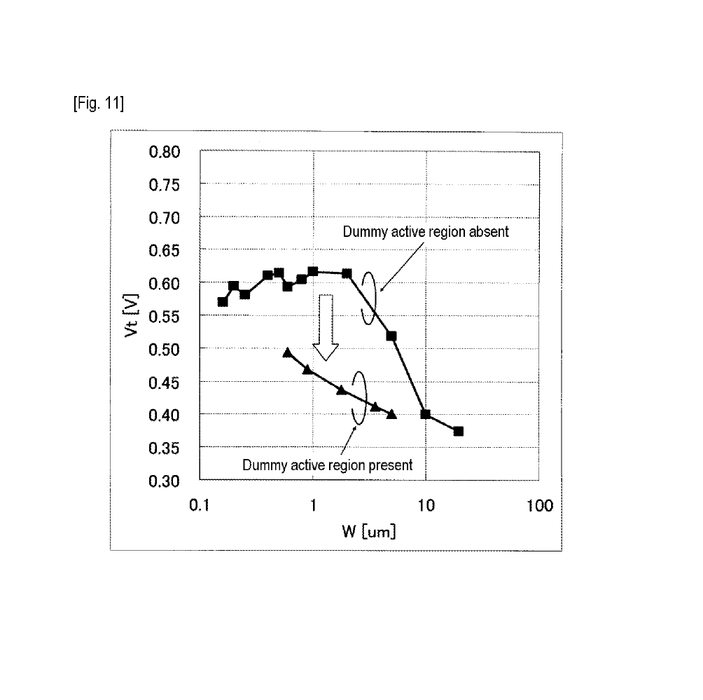

The process of manufacturing a semiconductor device 100 according to the first embodiment shown in FIG. 1 will now be described with reference to FIG. 12 to FIG. 15.

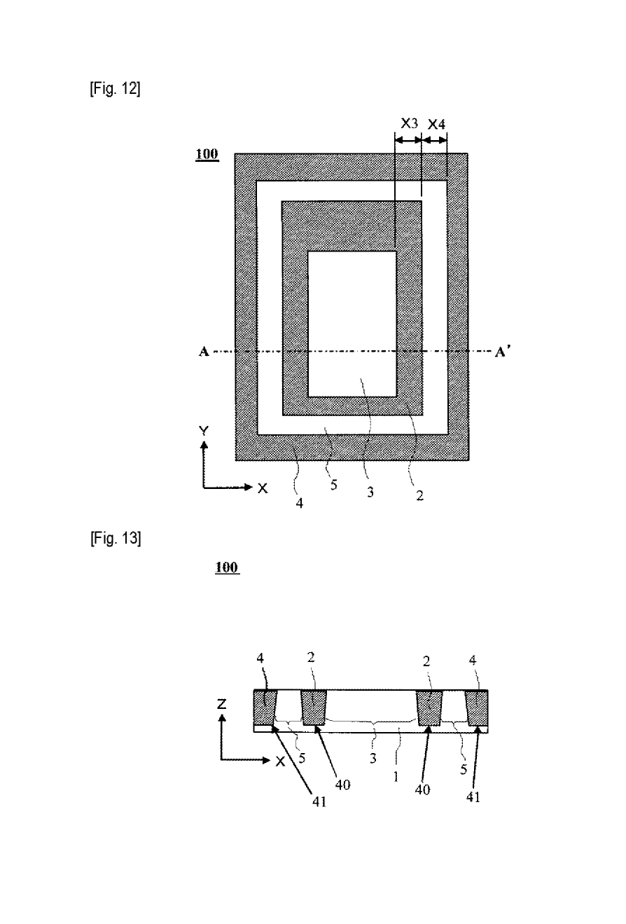

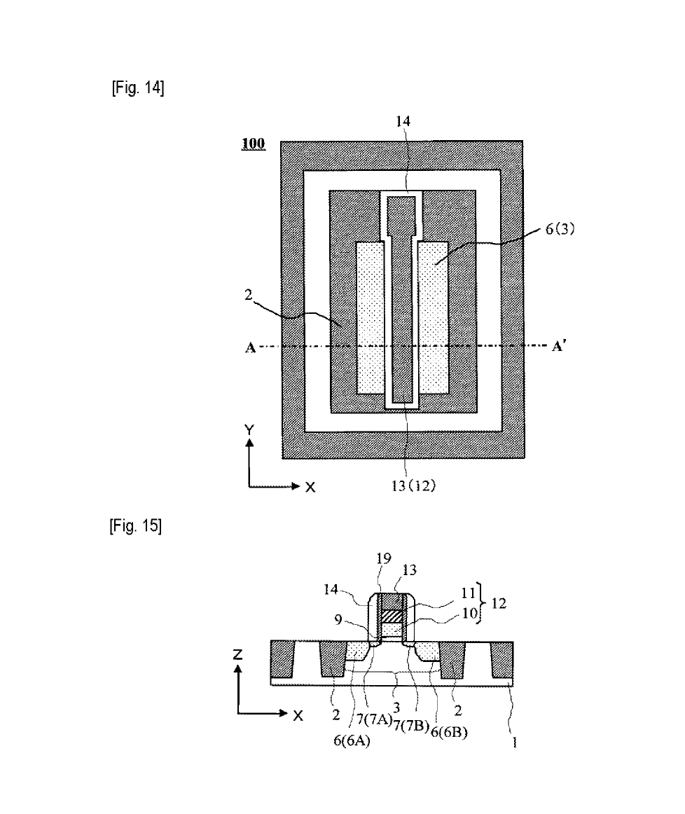

The views of FIG. 12 to FIG. 15 are diagrammatic views of the steps in the process of manufacturing a semiconductor device 100 as shown in FIG. 1. FIG. 12 is a plan view showing diagrammatically the step of forming the first active region 3, the first element isolating region 2, the dummy active region 5 and the second element isolating region 4 on the P type semiconductor substrate 1; FIG. 13 is a cross-sectional view showing diagrammatically the cross section A-A′ of FIG. 12. FIG. 14 is a plan view showing diagrammatically the step of forming an N type MOSFET adopting an HKMG construction in the first active region 3; FIG. 15 is a cross-sectional view showing diagrammatically the cross section A-A′ of FIG. 14.

(Step of Forming the First Active Region 3 and the Dummy Active Region 5)

Referring to FIG. 12 and FIG. 13, the step of forming the first active region 3, the first element isolating region 2, the dummy active region 5 and the second element isolating region 4 on the P type semiconductor substrate 1 will be described.

Using a photolithographic technique and dry etching technique, a first isolating trench 40 constituting the outsidewall of the first element isolating region 2, and a second isolating trench 41 constituting the outsidewall of the second element isolating region 4 are formed in the silicon substrate (P type semiconductor substrate) 1. In the semiconductor device 100 including an N type planar MOSFET shown in FIG. 1, the depth d_{trench-1} of the first isolating trench 40 and the depth d_{trench-2} of the second isolating trench 41 are each selected as 200 nm. As shown in FIG. 13, the silicon substrate (P type semiconductor substrate) 1 remains as a residual portion at the bottom of the first isolating trench 40 and the second isolating trench 41; the bottom of the first active region 3 and the bottom of the dummy active region 5 are electrically linked by the conductive path presented by this residual portion.

As shown in FIG. 13, the trench width W_{trench-1} of the first isolating trench 40 and the trench width W_{trench-2} of the second isolating trench 41 are somewhat wider at the top than at the bottom, the sidewall faces of the trenches being inclined.

Next, a buried insulating film made of silicon oxide film (SiO₂) or silicon nitride film (SiN) is deposited by the CVD (Chemical Vapor Deposition) method, so as to fill the interior of the first isolating trench 40 and the second isolating trench 41. The film thickness t_{buried-isolating-film} of this buried insulating film that is deposited in the interior of the first isolating trench 40 and the second isolating trench 41 is selected so as not to exceed the depth d_{trench-1} of the first isolating trench 40 and the depth d_{trench-2} of the second isolating trench 41. The first element isolating region 2 that demarcates the periphery of the first active region 3 and the second element isolating region 4 that demarcates the periphery of the dummy active region 5 are formed by removing the buried insulating film on the silicon substrate 1 by a CMP (Chemical Mechanical Polishing) technique. FIG. 12 shows an example of the width X3 of the portion extending in the Y direction of the first element isolating region 2 and the width X4 of the portion that extends in the Y direction of the dummy active region 5 formed in a region sandwiched by the first element isolating region 2 and the second element isolating region 4, in a semiconductor device 100 including an N type planar MOSFET, as shown in FIG. 1. In the semiconductor device 100 including the N type planar MOSFET shown in FIG. 1, regarding the width X3 of the portion extending in the Y direction of the first element isolating region 2, the width in the upper part thereof may be set in the range 0.1 μm to 2 μm and, regarding the width X4 of the portion extending in the Y direction of the dummy active region 5, the width in the upper part thereof may likewise be set in the range 0.1 μm to 2 μm.

Regarding the width X3 of the portion extending in the Y direction of the first element isolating region 2, depending on the case, in the first element isolating region 2 shown in FIG. 12 and FIG. 13, the width of the upper portion thereof may be set so as to satisfy the relationship 0.1 μm≦X3<d_{trench-1} in respect of the depth d_{trench-1} of the first isolating trench 40. Also, depending on the case, regarding the width X4 of the portion extending in the Y direction of the dummy active region 5, the width in the upper portion thereof may be set so as to satisfy the relationship 0.1 μm≦X4<d_{trench-1}, in respect of the depth d_{trench-1} of the first isolating trench 40.

(Step of Forming N Type Planar MOSFET)

A step of forming an N type planar MOSFET including a high dielectric constant insulating film in the gate insulating film 9 in the first element isolating region 2 will now be described with reference to FIG. 14 and FIG. 15.

On the silicon substrate 1, there are successively deposited: a silicon oxide film of thickness 5 nm by the thermal CVD technique, a gate insulating film 9 including a high dielectric constant insulating film, and a polysilicon (polycrystalline silicon) film of thickness 60 to 100 nm, utilized for the manufacture of the first conductive film 10. Next, impurity is selectively implanted in the polysilicon (polycrystalline silicon) film that is present within the periphery of the second element isolating region 4, using a photolithographic technique and ion implantation technique. Of the polysilicon (polycrystalline silicon) film, the portion where impurity implantation is selectively performed is utilized as the first conductive film 10 made of N type conductivity polysilicon (polycrystalline silicon) film. After implantation of impurity, a tungsten silicide (WSi) film (not shown) of thickness 5 nm produced by the CVD technique and a tungsten (W) film of thickness 45 nm produced by a sputtering technique are successively laminated onto the polysilicon (polycrystalline silicon) film. The tungsten silicide (WSi) film and the tungsten (W) film are utilized as the second conductive film 11. A silicon nitride film of thickness 200 nm is deposited by the CVD technique on the tungsten (W) film. The silicon nitride film is utilized as a mask film 13. Next, by a photolithographic technique and dry etching technique, a silicon oxide film or silicon nitride film is laminated on the silicon substrate 1, and unwanted portions are removed by etching, utilizing the pattern-shaped resist mask of the gate electrode shown in FIG. 14. By this patterning, there is formed the pattern of the gate electrode 12 (hereinbelow referred to as the gate pattern), which constitutes a laminated structure of a gate insulating film 9 made of silicon oxide film and high dielectric constant insulating film, a first conductive film 10 made of N type conductivity polysilicon (polycrystalline silicon) film, a tungsten silicide (WSi) film, the gate electrode 13 constituted by the second conductive film 11 made of tungsten (W) film and a mask film 13 made of silicon nitride film, as shown in FIG. 15.

Next, a silicon nitride film of thickness 12 nm is isotropically deposited by the ALD (Atomic Layer Deposition) technique on the gate pattern on the silicon substrate 1. The isotropically deposited silicon nitride film covers the mask film 13 of the gate pattern and the side faces of the gate pattern on the silicon substrate 1. After this, etching of the silicon nitride film that is deposited on the silicon substrate 1 and the mask film 13 is performed, with silicon nitride film being left behind so as to cover the side faces of the gate pattern, by employing an anisotropic etching technique. The silicon nitride film that covers the side faces of the gate pattern is employed as the spacer film 19.

Next, employing the photolithographic technique and ion implantation technique, impurity is implanted into the silicon substrate 1 utilizing as an ion implantation mask a resist mask that covers the region apart from the first active region 3 and the gate pattern provided with the spacer film 19 at the side faces. In this ion implantation step, a low-density doped region employed for the manufacture of the LDD regions 7A and 7B is formed in self-aligned fashion, by selecting a low density N_{LDD} for the density N_{LDD} of the implanted impurity and a shallow d_{LDD} for the implantation depth d_{LDD}.

Next, a silicon oxide film of thickness 40 nm is isotropically deposited by the ALD technique on the gate pattern on the silicon substrate 1. The isotropically deposited silicon oxide film covers the silicon substrate 1, the mask film 13 on the gate pattern, and the upper surface of the spacer film 19 provided on the side face of the gate pattern. After this, by etching back the silicon oxide film deposited on the silicon substrate 1 and the mask film 13 by employing an anisotropic etching technique, a silicon oxide film is left behind as a residual film covering the spacer film 19 provided on the side face of the gate pattern. This silicon oxide film that covers the spacer film 19 of the gate pattern side face is utilized as the sidewall insulating film 14.

Next, by using the photolithographic technique and ion implantation technique, impurity is implanted in the silicon substrate 1 utilizing as an ion implantation mask the resist mask covering the region other than the first active region 3 and the gate pattern with the spacer film 19 provided at the side faces. In this ion implantation step, a high-density doped region employed for the manufacture of the impurity diffusion layers 6A and 6B is formed in self-aligned fashion, by selecting a high density N_{HD} for the implanted impurity density N_{HD} and a large depth d_{HD} for the implantation depth d_{HD}. Formation of the LDD regions 7A and 7B and the impurity diffusion layers 6A and 6B shown in FIG. 15 is achieved by activation processing of the ion-implanted impurity.

The gate length L_{gate} of the N type planar MOSFET that has thus been manufactured corresponds to the distance in the X direction separating the two LDD regions 7A and 7B shown in FIG. 15. In contrast, the gate width W of the N type planar MOSFET that has thus been manufactured corresponds to the length in the Y direction of the portion formed in the interior of the first active region 3, of the gate pattern (gate electrode 12) shown in FIG. 14.

Next, a silicon oxide film produced by the CVD technique is deposited on the silicon substrate 1 so as to bury the gate pattern shown in FIG. 15. After this, a first interlayer insulating film 8 is formed by flattening the silicon oxide film that was thus deposited, until the surface of the mask film 13 is exposed, using the CMP technique. Furthermore, contact plugs (first contact plug 15 and second contact plug 17) passing through the first interlayer insulating film 8 and wirings (first wiring 16 and second wiring 18) that are employed for application of bias through the contact plugs are formed by known manufacturing methods.

By utilizing the manufacturing process described above, an N type planar MOSFET having the structure shown in FIG. 1 and FIG. 2 i.e. a semiconductor device 100 according to the first embodiment can be manufactured.

Manufacture of the semiconductor device 200 according to the second embodiment—the semiconductor device 900-1 according to the ninth embodiment, shown in FIG. 3—FIG. 10-2, can be achieved utilizing the same manufacturing process as the process of manufacturing the semiconductor device 100 according to the first embodiment. A separate description relating to the process of manufacture of the semiconductor device 200 according to the second embodiment—the semiconductor device 900-1 according to the ninth embodiment, shown in FIG. 3—FIG. 10-2, can therefore be dispensed with.

While the invention of the present application has been described with reference to modes of application (and embodiments) above, the invention of the present application is not restricted to the above-described modes for application (and embodiments). The construction and details of the invention of the present application can be modified in various ways that will be understood by persons skilled in the art, within the scope of the invention of the present application.

The present application claims priority based on the Japanese patent application 2013-50344 that was applied for on 13 Mar. 2013, and all the disclosure thereof is incorporated herein.

### POSSIBILITIES OF INDUSTRIAL APPLICATION

The semiconductor devices according to the present invention can be utilized in applications in which suppression of shift in the threshold voltage is desired, in particular semiconductor devices constituting peripheral circuits in DRAM memory cells.

1. A semiconductor device comprising:
a first active region provided on a semiconductor substrate, in which a transistor is arranged having a high dielectric constant gate insulating film and a gate electrode and a diffusion layer;
an element isolating region that contiguously surrounds said first active region; and
a dummy active region that is contiguous with said element isolating region.

2. The semiconductor device as claimed in claim 1, wherein the dummy active region comprises:
a first dummy active region that extends in a first direction; and
a second dummy active region that extends in a second direction different from said first direction, contiguous with said first dummy active region.

3. The semiconductor device as claimed in claim 1, wherein the dummy active region comprises a first dummy active region and a second dummy active region that face each other in a first direction, and said first active region is arranged between said first dummy active region and said second dummy active region.

4. The semiconductor device as claimed in claim 2, wherein the dummy active region further comprises a third dummy active region contiguous with said first dummy active region and said second dummy active region.

5. The semiconductor device as claimed in claim 3, wherein the dummy active region further comprises a third dummy active region and fourth dummy active region contiguous with said first dummy active region and said second dummy active region, and the dummy active region is arranged so as to surround said first active region, being continuous with said first dummy active region, said second dummy active region, said third dummy active region and said fourth dummy active region.

6. The semiconductor device as claimed in claim 3, wherein the dummy active region further comprises a fifth dummy active region and a sixth dummy active region that face each other in a second direction different from said first direction, and the dummy active region is arranged so as to surround said first active region, with said first dummy active region, said second dummy active region, said fifth dummy active region and said sixth dummy active region.

7. The semiconductor device as claimed in claim 1, wherein the high dielectric constant gate insulating film includes:
at least one material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃.

8. The semiconductor device as claimed in claim 1, wherein the gate electrode includes at least one metallic element selected from the group consisting of Ti, W, Ta, Ru and Al.

9. The semiconductor device as claimed in claim 1, wherein impurity is implanted in said dummy active region.

10. The semiconductor device as claimed in claim 9, wherein the conduction type of said diffusion layer and the conduction type of said impurity that is implanted in said dummy active region are the same.

11. The semiconductor device as claimed in claim 5, wherein a plurality of transistors respectively having a high dielectric constant gate insulating film, a gate electrode and a diffusion layer are arranged in the region surrounded by the element isolating region that is surrounded by said dummy active region.

12. The semiconductor device as claimed in claim 1, wherein a plurality of semiconductor devices are provided on said semiconductor substrate and said plurality of semiconductor devices include at least one dummy active region.

13. The semiconductor device as claimed in claim 1, wherein the dummy active region extends in the first direction, and further comprises a first diffusion layer and second diffusion layer that are contiguous with said element isolating region and extend in the second direction different from said first direction, with said first active region arranged therebetween, and a third diffusion layer that extends in said first direction, is connected with said first diffusion layer and said second diffusion layer, with said first active region arranged between this and said dummy active region, and said first diffusion layer, said second diffusion layer and said third diffusion layer are supplied with a fixed potential.

14. A semiconductor device comprising:
provided on a semiconductor substrate,
a first transistor having a first high dielectric constant gate insulating film, a first metal gate electrode, a first diffusion layer and a second diffusion layer;
a second transistor having a second high dielectric constant gate insulating film, a second metal gate electrode, and said second diffusion layer and third diffusion layer;
a first element isolating region surrounding and contiguous with said first diffusion layer, said second diffusion layer and said third diffusion layer;
a first dummy active region contiguous with and surrounding on four sides said first element isolating region; and
a second element isolating region contiguous with and surrounding on four sides said first dummy active region.

15. The semiconductor device as claimed in claim 14, wherein the first metal gate electrode and said second metal gate electrode extend in intersecting fashion over said first dummy active region and are connected by the first gate wiring.

16. The semiconductor device as claimed in claim 15, wherein there are provided on said semiconductor substrate:
a third transistor having a third high dielectric constant gate insulating film, a third metal gate electrode, a fourth diffusion layer and a fifth diffusion layer;
a fourth transistor having a fourth high dielectric constant gate insulating film, a fourth metal gate electrode, said fifth diffusion layer and sixth diffusion layer;
a third element isolating region contiguous with and surrounding said fourth diffusion layer, said fifth diffusion layer and said sixth diffusion layer;
a second dummy active region contiguous with and surrounding on four sides said third element isolating region; and
a fourth element isolating region contiguous with and surrounding on four sides said second dummy active region;
wherein said third metal gate electrode and said fourth metal gate electrode extend in intersecting fashion over said second dummy active region and are connected by the second gate wiring, and said first gate wiring and said second gate wiring are connected through the first conductive wiring.

17. The semiconductor device as claimed in claim 16, wherein the first transistor and said second transistor are N channel-type transistors and said third transistor and said fourth transistor are P channel-type transistors.

18. The semiconductor device as claimed in claim 17, wherein the input signal terminal is connected with said first conductive wiring, a first potential is supplied to said first diffusion layer and said third diffusion layer, a second potential is supplied to said fourth diffusion layer and said sixth diffusion layer, and said second diffusion layer and said fifth diffusion layer are connected with the output signal terminal through the second conductive wiring.

19. The semiconductor device as claimed in claim 17, wherein the respective conduction types of said first diffusion layer, said second diffusion layer and said third diffusion layer, and the conduction type of the first impurity that is implanted in said first dummy active region are N type, and the respective conduction types of said fourth diffusion layer, said fifth diffusion layer and said sixth diffusion layer, and the conduction type of the second impurity that is implanted in said second dummy active region are P type.

20. The semiconductor device as claimed in claim 14, wherein the first high dielectric constant gate insulating film, said second high dielectric constant gate insulating film, said third high dielectric constant gate insulating film and said fourth high dielectric constant gate insulating film respectively include at least one material selected from the group consisting of HfSiON, ZrO₂, Ta₂O₅, Nb₂O₅, Al₂O₃, HfO₂, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, Ho₂O₃, Er₂O₃, Tm₂O₃, Yb₂O₃, and Lu₂O₃, and said first metal gate electrode, said second metal gate electrode, said third metal gate electrode and said fourth metal gate electrode respectively include at least one metallic element selected from the group consisting of Ti, W, Ta, Ru and Al.
